(19) United States
(12) Patent Application Publication
(10) Pub. No.: US 2026/0324193 A1
(43) Pub. Date: Oct. 15, 2026

(54) DISPLAY DEVICE, ELECTRONIC EQUIPMENT, AND MANUFACTURING METHOD OF DISPLAY DEVICE

(71) Applicant: SONY SEMICONDUCTOR SOLUTIONS CORPORATION, KANAGAWA (JP)

(72) Inventor: Hiroshi FUJIMAKI, KANAGAWA (JP)

(21) Appl. No.: 19/119,062

(22) PCT Filed: Sep. 5, 2023
(86) PCT No.: PCT/JP2023/032313

§ 371 Date: Apr. 7, 2025

(30) Foreign Application Priority Data
Oct. 14, 2022 (JP) 2022-165301

(51) Int. Cl. H10K 50/84; H10K 59/12; H10K 59/122; H10K 59/35

(52) U.S. Cl. CPC H10K 50/84; H10K 59/1201; H10K 59/122; H10K 59/35

(57) ABSTRACT

For example, there are provided a display device, electronic equipment, and a manufacturing method of the display device capable of preventing entry of moisture or the like into an effective pixel region.
A display device includes a drive substrate including an effective pixel region and a peripheral region between the effective pixel region and an outer edge portion, in which the effective pixel region includes a plurality of pixels, each of the pixels includes a first electrode, a second electrode disposed opposite to the first electrode, and a first organic layer provided between the first electrode and the second electrode and including a light emitting layer, and the peripheral region includes a second organic layer separated from the first organic layer included in the pixel.

### TECHNICAL FIELD

The present disclosure relates to a display device, electronic equipment, and a manufacturing method of the display device.

### BACKGROUND ART

In recent years, organic light emitting diode (OLED) devices have been applied not only to direct-view displays such as monitors and smartphones but also to ultra-small displays (microdisplays) requiring a pixel pitch of several microns. Moreover, the OLED devices are being considered for use in applications such as augmented reality (AR) and virtual reality (VR). In the VR and the like, higher definition and higher color gamut are desired for enjoying a video, and OLED devices with high reliability are required.

Meanwhile, since an organic material constituting the OLED device is deteriorated by moisture or the like, when liquid such as moisture enters from an outer periphery of a panel, dust, a defect portion, or the like and reaches an effective pixel, light emission failure or the like occurs. In order to avoid such inconvenience, there have been proposed a technique in which a water-refilling layer is provided on a light emitting element separation layer for separating a light emitting element to prevent water from entering an organic material (see Patent Document 1 below), and an OLED device containing a desiccant or a moisture absorbent.

### CITATION LIST

### Patent Document

Patent Document 1: Japanese Patent Application Laid-Open No. 2010-205625

### SUMMARY OF THE INVENTION

### Problems to be Solved by the Invention

However, in the technique of Patent Document 1 and the like, it is necessary to add a new layer configuration in order to prevent water immersion, and thus, there is a possibility of causing an increase in cost and complication of processes.

An object of the present disclosure is to provide a display device, electronic equipment, and a manufacturing method of the display device capable of preventing entry of moisture and the like into an effective pixel region while suppressing an increase in cost and complication of processes as much as possible.

### Solutions to Problems

The present disclosure is, for example, a display device including
a drive substrate including an effective pixel region and a peripheral region between the effective pixel region and an outer edge portion,
in which the effective pixel region includes a plurality of pixels,
each of the pixels includes a first electrode, a second electrode disposed opposite to the first electrode, and a first organic layer provided between the first electrode and the second electrode and including a light emitting layer, and
the peripheral region includes a second organic layer separated from the first organic layer included in the pixel.

The present disclosure may be electronic equipment including the above-described display device.

The present disclosure is, for example, a manufacturing method of a display device, the manufacturing method including:
forming a pixel in an effective pixel region of a drive substrate, the pixel including a first electrode, a second electrode disposed opposite to the first electrode, and a first organic layer provided between the first electrode and the second electrode and including a light emitting layer; and
forming a second organic layer in a peripheral region between the effective pixel region and an outer edge portion of the drive substrate, the second organic layer being separated from the first organic layer included in the pixel.

### BRIEF DESCRIPTION OF DRAWINGS

FIG. 1 is a diagram for explaining a configuration example of a display device according to a first embodiment of the present disclosure.

FIG. 2 is a diagram for explaining a configuration example of a display device according to the first embodiment of the present disclosure.

FIG. 3 is a diagram for explaining a configuration example of a display device according to the first embodiment of the present disclosure.

FIG. 4 is a diagram for explaining a configuration example of a display device according to the first embodiment of the present disclosure.

FIG. 5 is a cross-sectional view for explaining a configuration example of a display device according to the first embodiment of the present disclosure.

FIG. 6 is a partially enlarged view in which the vicinity of a light emitting element of the display device according to the first embodiment of the present disclosure is enlarged.

FIG. 7 is a partially enlarged view in which the vicinity of a barrier portion of the display device according to the first embodiment of the present disclosure is enlarged.

FIG. 8 is a diagram for explaining an example of a manufacturing method of the display device according to the first embodiment of the present disclosure.

FIG. 9 is a diagram for explaining an example of a manufacturing method of the display device according to the first embodiment of the present disclosure.

FIG. 10 is a diagram for explaining an example of a manufacturing method of the display device according to the first embodiment of the present disclosure.

FIG. 11 is a diagram for explaining an example of a manufacturing method of the display device according to the first embodiment of the present disclosure.

FIG. 12 is a diagram for explaining an example of a manufacturing method of the display device according to the first embodiment of the present disclosure.

FIG. 13 is a partially enlarged view in which the vicinity of a barrier portion of a display device according to a second embodiment of the present disclosure is enlarged.

FIG. 14 is a partially enlarged view in which the vicinity of a barrier portion of a display device according to a third embodiment of the present disclosure is enlarged.

FIG. 15 is a plan view of a display device according to a fourth embodiment.

FIG. 16 is a plan view of a display device according to a fifth embodiment.

FIG. 17 is a plan view of a display device according to a sixth embodiment.

FIG. 18 is a plan view of the display device according to the sixth embodiment.

FIG. 19 is a plan view of a display device according to a seventh embodiment.

FIG. 20 is a plan view of a display device according to an eighth embodiment.

FIG. 21 is a partial cross-sectional view of a display device according to a ninth embodiment.

FIG. 22 is a partial cross-sectional view of a display device according to a tenth embodiment.

FIG. 23A to 23C are partial cross-sectional views of a display device according to an eleventh embodiment.

FIG. 24 is a plan view of a display device according to an eleventh embodiment.

FIG. 25A is a schematic cross-sectional view for explaining a first example of a resonator structure.

FIG. 25B is a schematic cross-sectional view for explaining a second example of the resonator structure.

FIG. 26A is a schematic cross-sectional view for explaining a third example of the resonator structure.

FIG. 26B is a schematic cross-sectional view for explaining a fourth example of the resonator structure.

FIG. 27A is a schematic cross-sectional view for explaining a fifth example of the resonator structure.

FIG. 27B is a schematic cross-sectional view for explaining a sixth example of the resonator structure.

FIG. 28 is a schematic cross-sectional view for explaining a seventh example of the resonator structure.

FIGS. 29A, 29B, and 29C are conceptual diagrams each explaining a relationship among a normal line LN passing through a center of a light emitting unit, a normal line LN′ passing through a center of a lens member, and a normal line LN″ passing through a center of a wavelength selection unit.

FIG. 30 is a conceptual diagram for explaining a relationship among a normal line LN passing through a center of a light emitting unit, a normal line LN′ passing through a center of a lens member, and a normal line LN″ passing through a center of a wavelength selection unit.

FIGS. 31A and 31B are conceptual diagrams each explaining a relationship among a normal line LN passing through a center of a light emitting unit, a normal line LN′ passing through a center of a lens member, and a normal line LN″ passing through a center of a wavelength selection unit.

FIG. 32 is a conceptual diagram for explaining a relationship among a normal line LN passing through a center of a light emitting unit, a normal line LN′ passing through a center of a lens member, and a normal line LN″ passing through a center of a wavelength selection unit.

FIG. 33A is a front view illustrating an example of an external appearance of a digital still camera. FIG. 33B is a back view illustrating an example of an external appearance of the digital still camera.

FIG. 34 is a perspective view illustrating an example of an external appearance of a head-mounted display.

FIG. 35 is a perspective view illustrating an example of an external appearance of a television device.

FIG. 36 is a perspective view illustrating an example of an external appearance of a see-through head-mounted display.

FIG. 37 is a perspective view illustrating an example of an external appearance of a smartphone.

FIG. 38A is a diagram illustrating an example of an interior state of a vehicle as viewed from the rear to the front of the vehicle. FIG. 38B is a diagram illustrating an example of an internal state of the vehicle as viewed from the oblique rear to the oblique front of the vehicle.

### MODE FOR CARRYING OUT THE INVENTION

Hereinafter, embodiments and the like of the present disclosure will be described below with reference to the drawings. Note that the description will be given in the following order.
<First embodiment>
<Second embodiment>
<Third embodiment>
<Fourth embodiment>
<Fifth embodiment>
<Sixth embodiment>
<Seventh embodiment>
<Eighth embodiment>
<Ninth embodiment>
<Tenth embodiment>
<Eleventh embodiment>
<Twelfth embodiment>
<Example of resonator structure applied to embodiment>
<Relationship among normal lines passing through respective centers of light emitting unit, lens member, and wavelength selection unit>
<Application examples>
<Modifications>

The embodiments and the like to be described below are preferred specific examples of the present disclosure, and the content of the present disclosure is not limited to the embodiments and the like. Note that, in the following description, components having substantially the same functional configuration are denoted by the same reference sign, and redundant description will be omitted as appropriate. Furthermore, in order to prevent the illustration from being complicated, there is a case where only a part of the configuration is denoted by reference signs, or there is a case where the illustration is simplified or enlarged/reduced. Furthermore, directions of up and down, left and right, and the like are defined in consideration of convenience of description, but the content of the present disclosure is not limited by these directions in the description.

### First Embodiment

### [Configuration Example of Display Device]

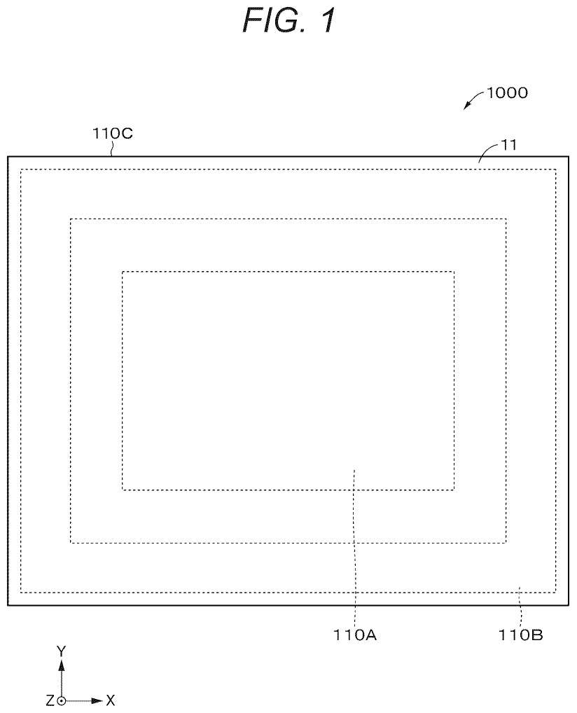

A configuration example of a display device (display device 1000) according to a first embodiment of the present disclosure will be described with reference to FIGS. 1, 2, 3, and 4. As schematically illustrated in FIG. 1, the display device 1000 includes a drive substrate 11. The drive substrate 11 includes, on one principal surface thereof, an effective pixel region 110A, and a peripheral region 110B provided near a peripheral edge between the effective pixel region 110A and an outer edge portion 110C of the drive substrate 11. The outer edge portion 110C of the drive substrate 11 coincides with a scribe line at the time when the drive substrate 11 is divided into individual pieces, but may not strictly coincide with the scribe line and may be in the vicinity thereof.

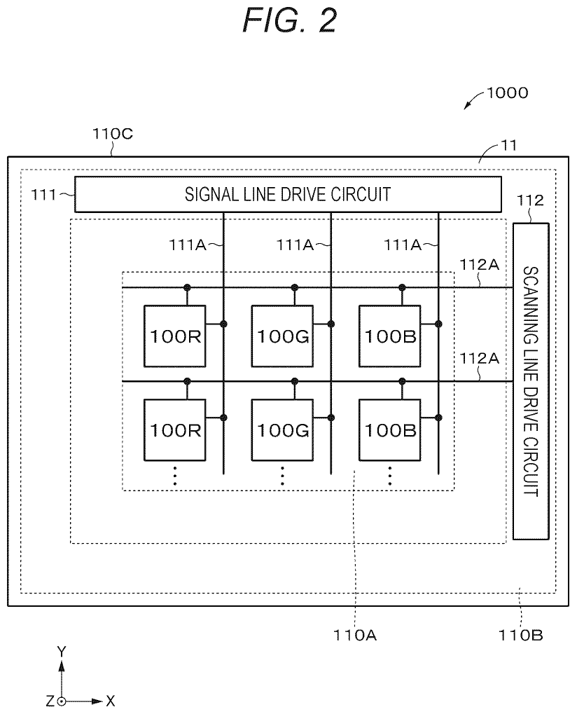

The effective pixel region 110A is a region determined as a region where light generated by a plurality of light emitting elements is emitted. A plurality of pixels is provided in the effective pixel region 110A. Specifically, as illustrated in FIG. 2, in the effective pixel region 110A, a plurality of subpixels 100R, 100G, and 100B is two-dimensionally arranged in a prescribed arrangement pattern such as a matrix.

The subpixels 100R display red, the subpixels 100G display green, and the subpixels 100B display blue. Note that, in a case where the subpixels 100R, 100G, and 100B are collectively referred to without being particularly distinguished from each other in the following description, the subpixels are referred to as subpixels 100. A combination of the adjacent subpixels 100R, 100G, and 100B constitutes one pixel. FIG. 2 illustrates an example in which a combination of the three subpixels 100R, 100G, and 100B aligned in a row direction (horizontal direction) constitutes one pixel, but the alignment of the subpixels 100R, 100G, and 100B is not limited thereto.

As illustrated in FIG. 2, in the peripheral region 110B, a signal line drive circuit 111 and a scanning line drive circuit 112, which are drivers for video display, are provided. Pads for connecting to these drive circuits may be provided in the peripheral region 110B. The signal line drive circuit 111 supplies a signal voltage of a video signal according to luminance information supplied from a signal supply source (not illustrated), to the subpixel 100 selected via a signal line 111A. The scanning line drive circuit 112 is constituted of a shift register or the like that sequentially shifts (transfers) a start pulse in synchronization with an input clock pulse. The scanning line drive circuit 112 scans the video signal when being written to each of the subpixels 100 row by row and sequentially supplies scanning signals to scanning lines 112A.

The display device 1000 may be a microdisplay. The display device 1000 may be provided in a VR device, a mixed reality (MR) device, an AR device, an electronic view finder (EVF), a small projector, or the like.

In the present embodiment, a case where the display device 1000 performs display by a top emission method is described as an example. The top emission method indicates a method in which a light emitting element is disposed closer to a light emitting surface side than the drive substrate 11. Accordingly, in the display device 1000, the drive substrate 11 is located on a back surface side of the display device 1000 and a direction (+Z direction) from the drive substrate 11 toward a light emitting element as described later is a front surface side (upper surface side) direction of the display device 1000. In the display device 1000, light generated from the light emitting element is directed in the +Z direction, and is emitted to the outside. In the following description, in each layer constituting the display device 1000, a surface on a display surface side in a display area (the effective pixel region 110A) of the display device 1000 is referred to as a first surface (upper surface), and a surface on a back surface side of the display device 1000 is referred to as a second surface (lower surface). Note that this does not prohibit the case where the display device according to the present disclosure is of a bottom emission method. The display device according to the present disclosure is also applicable to the bottom emission method. By the bottom emission method, light generated from the light emitting element is directed in a −Z direction, and is emitted to the outside.

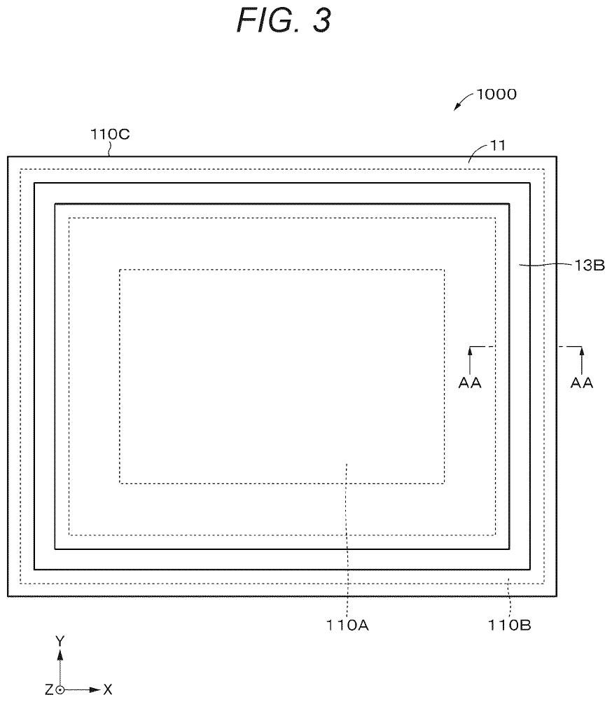

As illustrated in FIG. 3, a second organic layer 13B including an organic material is formed in the peripheral region 110B, specifically, inside the signal line drive circuit 111 and the scanning line drive circuit 112 in the peripheral region 110B. The second organic layer 13B is formed to have a frame shape surrounding the effective pixel region 110A in a case where the drive substrate 11 is plane-viewed. The second organic layer 13B will be described later in detail, and therefore will be described schematically here.

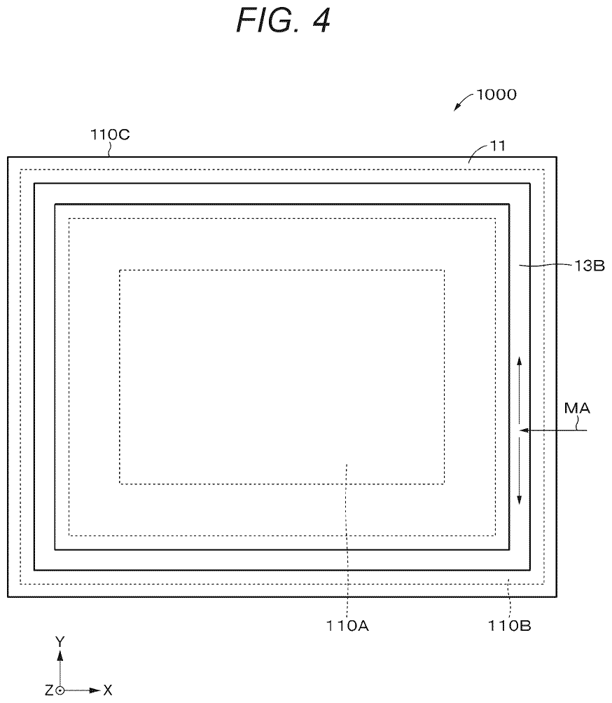

The second organic layer 13B functions as a barrier surrounding the effective pixel region 110A. For example, as schematically illustrated in FIG. 4, it is assumed that moisture enters from the outer edge portion 110C of the drive substrate 11. In FIG. 4, a propagation path of the moisture that has entered is schematically indicated by an arrow MA. The moisture entering from the outer edge portion 110C reaches the second organic layer 13B as indicated by the arrow MA. Here, the second organic layer 13B includes an organic material. Since the organic material has higher water permeability than an inorganic material, the moisture that has entered the second organic layer 13B does not go toward the effective pixel region 110A but travels in the second organic layer 13B as indicated by the arrow MA. Thus, entry of moisture into the effective pixel region 110A can be prevented.

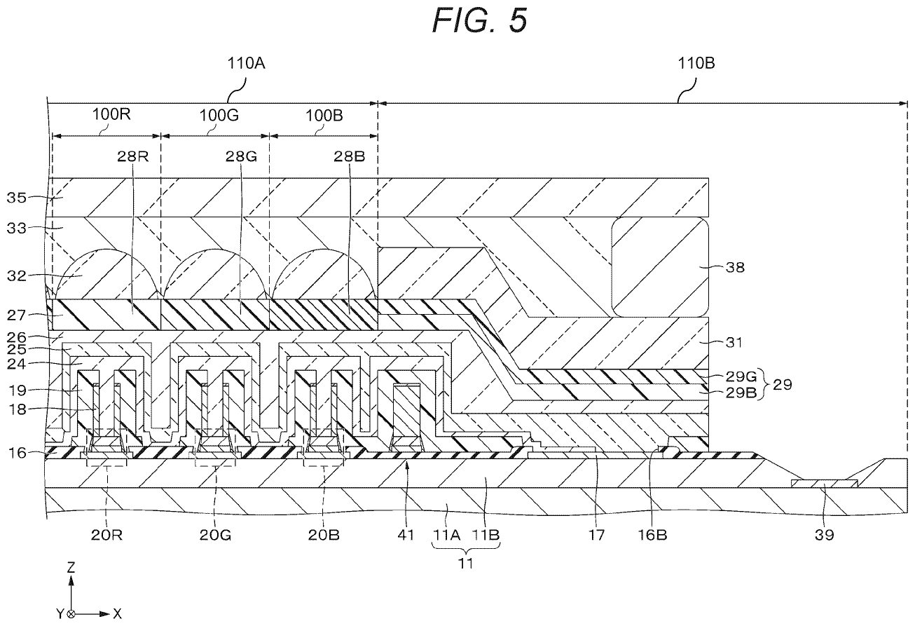

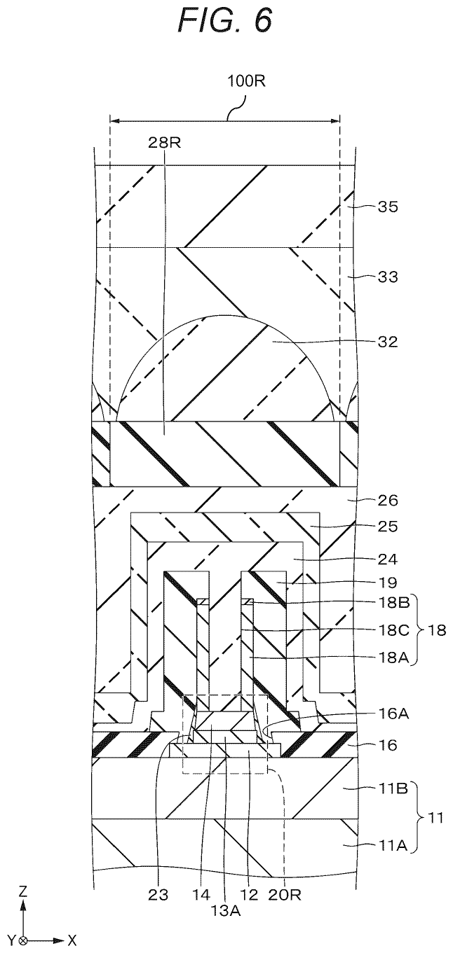

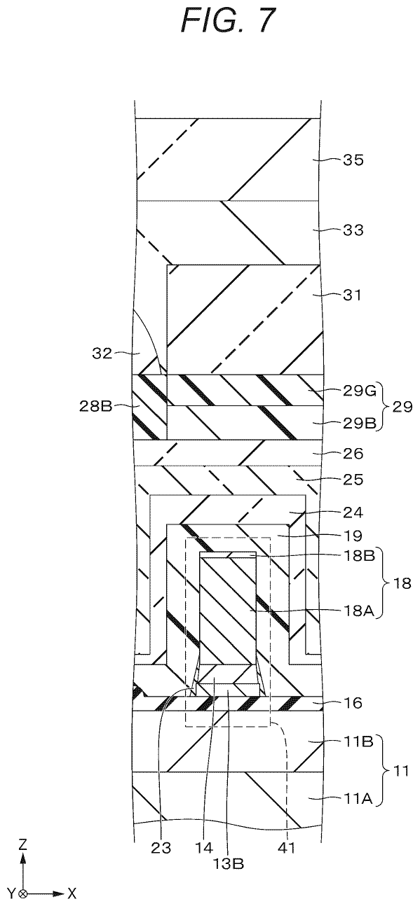

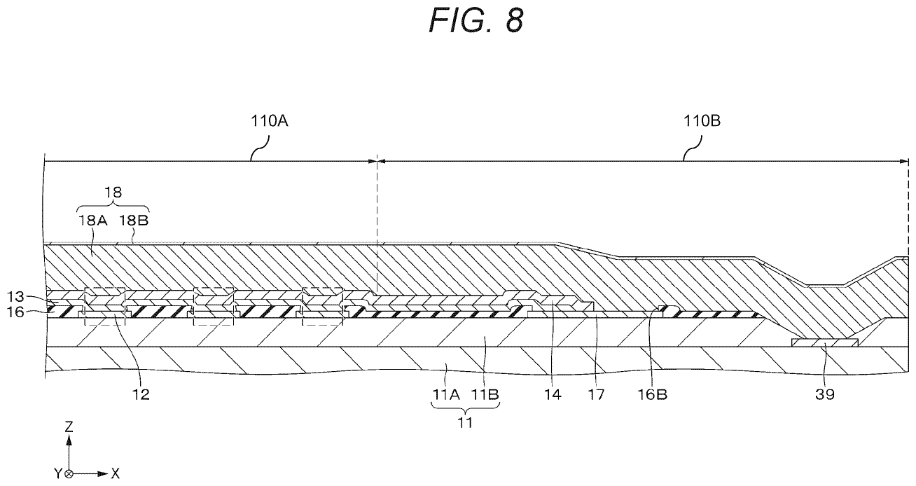

Next, a configuration example of the display device 1000 will be described in detail with reference to FIGS. 5, 6, and 7. FIG. 5 is a diagram illustrating a cross section of the display device 1000 in a case where the display device is cut along a cutting line AA-AA in FIG. 3. Furthermore, FIG. 6 is an enlarged view illustrating the vicinity of a light emitting element (for example, a light emitting element 20R of the subpixel 100R) in FIG. 5. Furthermore, FIG. 7 is an enlarged view illustrating the vicinity of a barrier portion (barrier portion 41 described later) in FIG. 5.

The display device 1000 includes a plurality of light emitting elements 20. The plurality of light emitting elements 20 includes a first electrode 12, a first organic layer 13A as an example of an organic layer including a light emitting layer, and a second electrode 14 (see FIG. 6). The light emitting element 20 is, for example, a white light emitting element such as a white OLED or a white Micro-OLED (MOLED). As a coloring method in the display device 1000, a method using a white light emitting element and a color filter (color filter 27 described later) is used.

### (Drive Substrate)

As illustrated in FIG. 5, the display device 1000 includes the drive substrate 11. The drive substrate 11 is a so-called backplane and drives the plurality of light emitting elements 20. The drive substrate 11 includes, for example, a base material 11A and an interlayer insulating layer 11B layered on the base material 11A. The interlayer insulating layer 11B may be layered and formed on the base material 11A, or a part thereof may be directly formed on the base material 11A by a semiconductor process.

The base material 11A may be a semiconductor substrate such as a silicon substrate, may be a glass substrate or quartz having low moisture and oxygen permeability, or an insulator substrate such as resin. The semiconductor substrate includes, for example, amorphous silicon, polycrystalline silicon, monocrystalline silicon, or the like. As a specific example, the glass substrate includes, for example, high strain point glass, soda glass, borosilicate glass, forsterite, lead glass, quartz glass, or the like. Furthermore, specific examples of the resin substrate include, for example, at least one kind selected from the group including polymethyl methacrylate, polyvinyl alcohol, polyvinyl phenol, polyethersulfone, polyimide, polycarbonate, polyethylene terephthalate, polyethylene naphthalate, and the like. The base material 11A has, for example, a thin plate shape. The base material 11A may have flexibility.

The interlayer insulating layer 11B includes an organic material or an inorganic material, for example. The organic material contains at least one material of polyimide or acrylic resin, for example. The inorganic material contains at least one material of silicon oxide, silicon nitride, silicon oxynitride, or aluminum oxide, for example.

In the interlayer insulating layer 11B, various circuits for driving the plurality of light emitting elements 20 are provided. Examples of the various circuits can include a drive circuit that controls driving of the light emitting elements 20, and a power supply circuit that supplies power to the plurality of light emitting elements 20 (none of which is illustrated). The various circuits are regulated from being exposed to the outside by the interlayer insulating layer 11B.

### (Light Emitting Elements)

The plurality of light emitting elements 20 is arranged on the first surface of the interlayer insulating layer 11B. Each of the light emitting elements 20 is, for example, an organic electroluminescent element (organic EL element). Each of the plurality of light emitting elements 20 emits a color corresponding to the color type of the subpixel 100 from a light emitting surface. For example, light emitting elements 20R, 20G, and 20B are formed in the subpixels 100R, 100G, and 100B, respectively. Furthermore, the plurality of light emitting elements 20 is laid out in a manner corresponding to the arrangement of the subpixels 100 of the respective color types. Note that, in the present specification, in a case where the types such as the light emitting elements 20R, 20G, and 20B are not particularly distinguished, a word referred to light emitting elements 20 is used.

Each of the light emitting elements 20 has a multilayer structure in which the first electrode 12, the first organic layer 13A, and the second electrode 14 are layered in this order. The first electrode 12, the first organic layer 13A, and the second electrode 14 are layered in this order from a side of the drive substrate 11 in a direction (+Z direction) from the second surface toward the first surface.

### (First Electrode)

A plurality of the first electrodes 12 is provided on a side of the first surface of the drive substrate 11. Each of the first electrodes 12 is, for example, an anode electrode.

The first electrode 12 includes at least one layer of a metal layer and a metal oxide layer. The first electrode 12 may include a single-layer film of a metal layer or a metal oxide layer, or a multilayer film of a metal layer and a metal oxide layer.

The metal layer contains at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may include the at least one metal element described above as a constituent element of an alloy. Specific examples of the alloy include an aluminum alloy and a silver alloy. Specific examples of the aluminum alloy include, for example, AlNd and AlCu.

The metal oxide layer contains at least one of a mixture of indium oxide and tin oxide (ITO), a mixture of indium oxide and zinc oxide (IZO), or titanium oxide (TiO), for example.

The first electrode 12 is electrically separated for each of the subpixels 100. That is, a plurality of the first electrodes 12 is provided on the first surface side of the drive substrate 11, and each first electrode is provided for each subpixel 100.

### (First Organic Layer)

The first organic layer 13A is an organic light emitting layer provided between the first electrode 12 and the second electrode 14. The first organic layer 13A is provided separately for each subpixel 100. However, the first organic layer 13A may be configured to be provided in common to the subpixels 100. The first organic layer 13A is configured to be capable of emitting white light. However, this does not prohibit an emission color of the first organic layer 13A from being other than white, and colors including red, blue, green, and the like may be adopted. That is, the emission color of the first organic layer 13A may be, for example, any one of white, red, blue, and green.

The first organic layer 13A has, for example, a configuration in which a hole injection layer, a hole transport layer, a light emitting layer, and an electron transport layer are layered in this order from the first electrode 12 toward the second electrode 14. The electron injection layer may be provided between the electron transport layer and the second electrode 14. The electron injection layer is for enhancing electron injection efficiency. Note that the configuration of the first organic layer 13A is not limited thereto, and layers other than the light emitting layer are provided as necessary.

The hole injection layer is a buffer layer for enhancing hole injection efficiency into the light emitting layer and reducing leakage. The hole transport layer is for enhancing efficiency of hole transport to the light emitting layer. The electron transport layer is for enhancing efficiency of electron transport to the light emitting layer.

The light emitting layer generates light by recombination of electrons and holes when an electric field is applied. The light emitting layer is an organic compound layer containing an organic light emitting material.

### (Second Electrode)

The second electrode 14 is provided on an upper side of the first organic layer 13A. The second electrode 14 is, for example, a cathode. A portion of the second electrode 14 corresponding to the subpixel 100 (a portion corresponding to the light emitting element 20) is provided so as to face the first electrode 12. The second electrode 14 is separately provided for each of the plurality of subpixels 100. The second electrode 14 may be provided as a common electrode for the plurality of subpixels 100. The second electrode 14 is preferably a transparent electrode having transparency to light generated in the first organic layer 13A. The transparent electrode herein includes a transparent electrode including a transparent conductive layer, or a transparent electrode having a multilayer structure including a transparent conductive layer and a semi-transmissive reflective layer.

As the transparent conductive layer, a transparent conductive material having good optical transparency and a small work function is preferably used. The transparent conductive layer can include a metal oxide, for example. Specifically, examples of the material of the transparent conductive layer can include a material containing at least one of a mixture of indium oxide and tin oxide (ITO), a mixture of indium oxide and zinc oxide (IZO), or zinc oxide (ZnO).

The semi-transmissive reflective layer can include a metal layer, for example. Specifically, examples of the material of the semi-transmissive reflective layer can include a material containing at least one metal element selected from the group consisting of magnesium (Mg), aluminum (Al), silver (Ag), gold (Au), and copper (Cu). The metal layer may include the at least one metal element described above as a constituent element of an alloy. Specific examples of the alloy include an MgAg alloy, an AgPdCu alloy, and the like.

### (Interpixel Insulating Layer)

A layer having insulating properties is preferably formed between the first electrodes 12 adjacent to each other. In the examples of FIGS. 5 and 6, an interpixel insulating layer 16 is formed between the adjacent first electrodes 12. The interpixel insulating layer 16 may be an organic insulating layer, an inorganic insulating layer, or a multilayer body constituted of these layers. The organic insulating layer includes, for example, at least one kind selected from the group including polyimide-based resin, acrylic resin, novolac-based resin, and the like. The inorganic insulating layer includes, for example, at least one kind selected from the group including silicon oxide (SiOx), silicon nitride (SiNx), silicon oxynitride (SiOxNy), and the like.

The interpixel insulating layer 16 electrically separates each first electrode 12 for each light emitting element 20 (that is, for each subpixel 100).

Furthermore, as illustrated in FIG. 6, an opening 16A is formed in the interpixel insulating layer 16 on the first surface side, the first surface of the first electrode 12 (the surface facing the second electrode 14) is exposed through the opening 16A of the interpixel insulating layer 16, and a portion of the first electrode 12 exposed through the opening 16A faces a first organic layer 13A described later while avoiding interposition of the interpixel insulating layer 16. Note that the interpixel insulating layer 16 may be formed not only between the adjacent first electrodes 12 but also so as to extend over the edge portions of the first electrodes 12. The edge portion of each of the first electrodes 12 is defined by a portion from an outer peripheral edge of the first electrode 12 to a predetermined position closer to a center side of the first electrode 12. Also in this case, the interpixel insulating layer 16 includes the opening 16A, and the first surface of the first electrode 12 is exposed from the opening 16A. Note that, in the present embodiment, the interpixel insulating layer 16 is formed not only over the effective pixel region 110A but also over the peripheral region 110B.

### (Cathode Contact)

Furthermore, an opening 16B is formed in the interpixel insulating layer 16 formed in the peripheral region 110B. A cathode contact 17 is exposed through the opening 16B. The cathode contact 17 is formed at a predetermined position on a first surface of the drive substrate 11 in the peripheral region 110B. The cathode contact 17 relays electrical connection between the various circuits formed in the interlayer insulating layer 11B and the second electrode 14. A material of the cathode contact 17 is not particularly limited as long as it is a conductive material, and for example, metal or the like can be used. The cathode contact 17 is formed in an annular shape so as to surround the periphery of the effective pixel region 110A in plan view of the drive substrate 11. However, the layout of the cathode contact 17 is not limited to an annular shape.

### (Protective Layer)

In the display device 1000, a protective layer 18 is formed so as to cover the first surface side of the light emitting element 20 (the first surface side of the second electrode 14). The protective layer 18 makes it difficult for the first surface of the light emitting element 20 to come into contact with the outside air, and suppresses entry of moisture into the light emitting element 20 from the external environment.

The protective layer 18 is formed with an insulating material. As the insulating material, thermosetting resin or the like can be used, for example. In addition, the insulating material may be SiO, SiON, AlO, Tio, or the like. In this case, examples of the protective layer 18 include a CVD film containing SiO, SiON, or the like, and an ALD film containing AlO, TiO, SiO, or the like. Note that the CVD film indicates a film formed using chemical vapor deposition. The ALD film indicates a film formed using atomic layer deposition. The protective layer 18 may be formed as a single layer or may have a structure in which a plurality of layers is layered. In the present embodiment, the protective layer 18 has a multilayer structure of a first protective layer 18A and a second protective layer 18B (see FIG. 6). The first protective layer 18A and the second protective layer 18B may be layers each including a predetermined insulating material, or the first protective layer 18A and the second protective layer 18B may include a CVD film and an ALD film, respectively.

### (Separation Protective Layer)

In the display device 1000, as an interelement separation wall, a separation protective layer 19 is formed so as to cover a side end surface of the light emitting element 20, a side end surface of the protective layer 18, and an upper end surface of the protective layer 18. The separation protective layer 19 is disposed between the adjacent light emitting elements 20, and separates the first electrode 12, the first organic layer 13A, and the second electrode 14 for each subpixel 100.

The separation protective layer 19 includes an insulator. Examples of the separation protective layer 19 include an inorganic insulating film and an organic insulating film. Examples of the inorganic insulating film include SiO2, SiN, and SiON. Examples of the organic insulating film include polyimide.

### (Sidewall Protective Layer)

A sidewall protective film 23 (see FIG. 6) is interposed between the side end surface of the first organic layer 13A, the second electrode 14, the lower side surface of the protective layer 18, and the separation protective layer 19. As illustrated in FIG. 6, the sidewall protective film 23 preferably covers the entire side end of the first organic layer 13A while being in contact with the side end surface of the first organic layer 13A.

The sidewall protective film 23 is an insulating film and is a processing by-product film containing a by-product (deposit) generated by etching processing. The sidewall protective film 23 assists formation of the separation protective layer 19 while regulating exposure of the first organic layer 13A to an external environment. Note that, as the etching processing, both the dry etching method and the wet etching method can be performed, but the etching processing is preferably the dry etching method from the viewpoint of more reliably realizing the deposition.

### (Auxiliary Electrode)

In the present embodiment, the second electrode 14 is separated for each subpixel 100. In correspondence with this configuration, the display device 1000 includes an auxiliary electrode 24. The auxiliary electrode 24 electrically connects the adjacent second electrodes 14 to each other. As illustrated in FIGS. 5 and 6, a groove 18C is formed in the protective layer 18 by etching processing or the like, and the auxiliary electrode 24 is connected to the second electrode 14 via the groove 18C. The auxiliary electrode 24 connected to each second electrode 14 is connected to the cathode contact 17 in the peripheral region 110B. That is, each second electrode 14 is connected to the cathode contact 17 via the auxiliary electrode 24. The auxiliary electrode 24 is a transparent electrode having transparency to light generated in the first organic layer 13A. Here, the transparent electrode also includes a semi-transparent reflection layer. As a material of the auxiliary electrode 24, the material similar to that of the second electrode 14 can be used.

### (Auxiliary Electrode Protective Layer)

An auxiliary electrode protective layer 25 is formed on the first surface of the auxiliary electrode 24. The auxiliary electrode protective layer 25 protects the auxiliary electrode 24. As a material of the auxiliary electrode protective layer 25, a material similar to that of the protective layer 18 can be used.

The auxiliary electrode protective layer 25 is formed not only over the effective pixel region 110A but also over a part of the peripheral region 110B.

### (Flattening Layer)

A flattening layer 26 is formed so as to cover the top (first surface) of the auxiliary electrode protective layer 25. The flattening layer 26 may be a layer including an inorganic material or a layer including an organic material. As the inorganic material, a material similar to that of the protective layer 18 can be exemplified. As the organic material, a material such as a resin material or the like can be exemplified. The flattening layer 26 can improve flatness of a surface on which the color filter 27 described later is formed. Furthermore, the flattening layer 26, together with the protective layer 18, makes it difficult for the first surface of the light emitting element 20 to come into contact with the outside air, and suppresses entry of moisture into the light emitting element 20 from the external environment. The flattening layer 26 is formed not only over the effective pixel region 110A but also over a part of the peripheral region 110B.

### (Color Filter)

In the display device 1000, the color filter 27 is provided on the first surface side (an upper side, the +Z direction side) of the flattening layer 26. As the color filter 27, an on chip color filter (OCCF) can be exemplified. As the color filter 27, a first color filter 28 and a second color filter 29 are provided. As a material of the color filter 27, an organic material can be exemplified.

### (First Color Filter)

The first color filter 28 is preferably formed generally in the effective pixel region 110A. Furthermore, the first color filter 28 is provided according to a color type of the subpixel 100. Examples of the first color filter 28 include, for example, a red color filter (red filter 28R), a green color filter (green FILTER 28G), and a blue color filter (blue filter 28B) in the example illustrated in FIG. 5. The red filter 28R, the green filter 28G, and the blue filter 28B are provided in the subpixels 100R, 100G, and 100B, respectively. Since the first color filter 28 is provided in the display device 1000, light corresponding to the color types of the subpixels 100R, 100G, and 100B can be effectively extracted to the outside.

### (Second Color Filter)

The second color filter 29 is formed outside the first color filter 28 (blue filter 28B in the present example) provided on the outermost side. In the example illustrated in FIG. 5, the second color filter 29 is generally formed in the peripheral region 110B. The second color filter 29 is formed so as to cover an upper side (+Z direction side) of the auxiliary electrode protective layer 25. The second color filter 29 functions as a layer having a light shielding property. The second color filter 29 has a structure in which a red color filter (red filter 29R) and a blue color filter (blue filter 29B) are layered. The red filter 29R may be formed simultaneously with the red filter 28R by using a similar material. The blue filter 29B may be formed simultaneously and integrally with the blue filter 28B by using a similar material.

The red filter 29R can be exemplified by, for example, a filter that easily allows light of a red wavelength band among visible light to pass through, and easily absorbs light of other color wavelength bands. The blue filter 29B can be exemplified by a filter that easily allows light of a blue wavelength band among visible light to pass through, and easily absorbs light of other color wavelength bands. According to such a structure in which the red filter 29R and the blue filter 29B are layered, light shielding can be achieved for light in wavelength bands of a wide range. Thus, among light generated by the light emitting element 20 in the effective pixel region 110A, light going to the outside from the peripheral region 110B in an oblique direction is suppressed from passing through the second color filter 29. Thus, an effect of suppressing light leakage by the second color filter 29 is exhibited. Light traveling from the outside of the display device 1000 toward the drive substrate 11 side is blocked by the second color filter 29, and entry of external light is suppressed.

As described above, the second color filter 29 has a light shielding property in a state where the red filter 29R and the blue filter 29B are layered, and the multilayer structure of the red filter 29R and the blue filter 29B functions as a light shielding filter.

(Seal layer)

A seal layer 31 is formed on the second color filter 29 (first surface). The seal layer 31 is formed in the peripheral region 110B with a thickness direction of the drive substrate 11 as a line-of-sight direction, and is formed in a region that covers at least a part (all in the present embodiment) of the second color filter 29. A material of the seal layer 31 is not particularly limited, but for example, a resin material having high moisture resistance can be applied. A hygroscopic material may be added to the seal layer 31.

### (Lens)

A lens 32 is formed on the first color filter 28 (on the first surface). In the example of FIG. 5, the lens 32 is provided in a layout corresponding to each subpixel 100. The lens 32 is preferably an on chip lends (OCL).

A shape of the lens 32 is not particularly limited. As the lens 32, a lens (so-called convex lens) formed in a convex shape having a curved surface convexly curved on the first surface side can be exemplified. Since the lens 32 is provided, it is easier to adjust light generated from the light emitting element 20 to be emitted from the effective pixel region 110A, and utilization efficiency of the light can be improved.

### (Filling Layer)

As illustrated in FIG. 5, a filling layer 33 is provided so as to cover the first surface side of the lens 32. By providing the filling layer 33, the first surface side of the effective pixel region 110A can be smoothed, and the lens 32 and the light emitting element 20 can be protected from outside air and moisture. Similarly to the seal layer 31 described above, the filling layer 33 is preferably a layer having a function as a transparent adhesive layer. As a material of the filling layer 33, a resin material may be used similarly to the seal layer 31 described above.

Note that, in the example of FIG. 5, the filling layer 33 is distinguished from the seal layer 31 described above, but this is an example, and the filling layer is not limited thereto. The filling layer 33 may be formed integrally with the seal layer 31.

### (Sealing Substrate)

A sealing substrate 35 is provided so as to cover the filling layer 33. As a material of the sealing substrate 35, the material of the base material 11A or the like can be used. For example, a glass substrate can be used as the sealing substrate 35. A material of the glass substrate is not particularly limited as long as the glass substrate includes a material that transmits light emitted from the light emitting element 20. Examples of the material of the glass substrate include various glass substrates such as high strain point glass, soda glass, borosilicate glass, and lead glass, and quartz substrates. The sealing substrate 35 is not limited to the glass substrate, and may be a plastic or a film. Furthermore, a structure such as a moth-eye may be formed on a facing surface of the sealing substrate 35. Furthermore, the sealing substrate 35 may not be provided as long as the filling layer 33 has sufficient strength.

### (Seal Portion)

As illustrated in FIG. 5, in the vicinity of the outer edge of the peripheral region 110B, a seal portion 38 is provided between the sealing substrate 35 and a surface of the drive substrate 11 on a side facing the sealing substrate 35. The seal portion 38 bonds together a peripheral edge portion of the facing surface of the sealing substrate 35 and a peripheral edge portion of the facing surface of the drive substrate 11 (more specifically, the seal layer 31 layered on the peripheral edge portion). As the seal portion 38, for example, a thermosetting resin can be applied. Note that the seal portion 38 may have the same configuration as the seal layer 31 and the filling layer 33.

### (Connection Terminal)

A connection terminal 39 is formed in the vicinity of the outer edge of the peripheral region 110B. The connection terminal 39 is formed outside an end surface of the seal portion 38, for example. The connection terminal 39 functions as a terminal for electrically connecting various circuits provided on the drive substrate 11 to external equipment such as another control circuit substrate, and the like. The connection terminal 39 is formed on the first surface of the base material 11A, for example. The connection terminal 39 is preferably a pad portion formed by a conductive member such as metal. The interlayer insulating layer 11B is formed around the connection terminal 39.

### (Barrier Portion)

The barrier portion 41 is formed at a predetermined location in the peripheral region 110B, for example, in the vicinity of a boundary between the effective pixel region 110A and the peripheral region 110B in the peripheral region 110B. FIG. 7 is an enlarged view illustrating the vicinity of the barrier portion 41 according to the present embodiment.

The barrier portion 41 includes at least the second organic layer 13B. The second organic layer 13B is separated from the first organic layer 13A. As illustrated in FIG. 7, the second organic layer 13B is formed on the first surface of the interpixel insulating layer 16 formed in the peripheral region 110B. Other configurations are substantially the same as the peripheral configuration of the light emitting element 20. That is, the second electrode 14 is formed on the first surface of the second organic layer 13B, and the protective layer 18 (the first protective layer 18A and the second protective layer 18B) is formed on the first surface of the second electrode 14. In the present embodiment, for example, the interpixel insulating layer 16, the second organic layer 13B, the second electrode 14, the protective layer 18, and the sidewall protective film 23 constitute the barrier portion 41.

As described above, the second organic layer 13B prevents entry of moisture or the like into the effective pixel region 110A. That is, it is not necessary to cause the second organic layer 13B to emit light. As a result, the protective layer 18 constituting the barrier portion 41 does not include the groove 18C. Since the groove 18C is not formed, the second electrode 14 included in the barrier portion 41 is not connected to the auxiliary electrode 24.

Each layer configuration constituting the barrier portion 41 is preferably formed in the same process as the corresponding layer configuration in the effective pixel region 110A. For example, the second organic layer 13B is preferably formed in the same process as the first organic layer 13A. Therefore, it is not necessary to add a new configuration or a process of forming the configuration, and it is possible to provide the highly reliable display device 1000 capable of preventing entry of moisture or the like.

The configuration of the display device 1000 described above is an example, and the display device according to the present disclosure is not limited to the exemplified configuration. Some of the exemplified configuration elements may be omitted, or other configuration elements may be added.

### [Manufacturing Method of Display Device]

Next, an example of a manufacturing method of the display device 1000 according to the first embodiment will be described. First, after a circuit and the like are mounted on the base material 11A, the interlayer insulating layer 11B is formed, and the connection terminal 39 and the like are formed. Next, a metal layer and a metal oxide layer are sequentially formed on the first surface of the drive substrate 11 by, for example, a sputtering method, and then, the metal layer and the metal oxide layer are patterned by using, for example, a photolithography technique and an etching technique. Therefore, the first electrode 12 and the cathode contact 17 are formed. Next, the interpixel insulating layer 16 is formed on the first surface of the drive substrate 11 in such a manner as to cover the plurality of first electrodes 12 by, for example, a chemical vapor deposition (CVD) method. Next, the opening 16A is formed in a portion of the interpixel insulating layer 16 located on the first surface of each first electrode 12 by, for example, a photolithography technique and a dry etching technique. The opening 16B is similarly formed in the cathode contact 17.

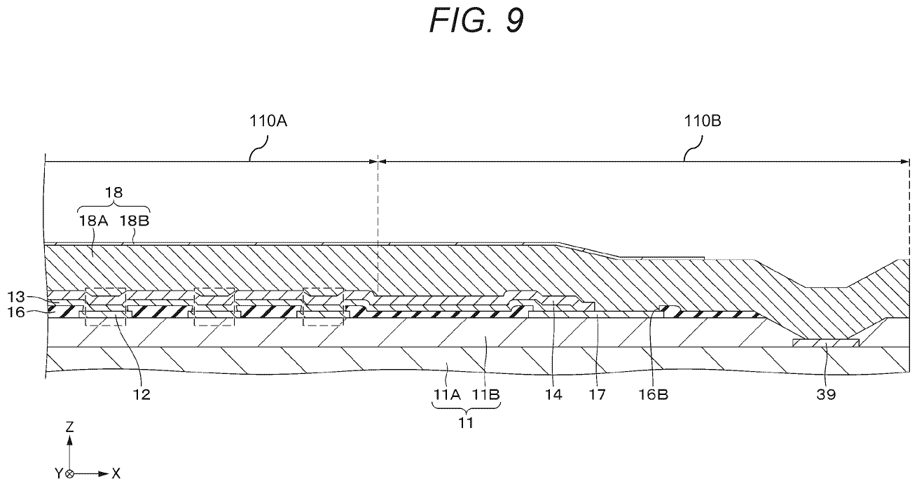

Next, the organic layer 13 is formed on the first surface of the first electrode 12 and the first surface of the interpixel insulating layer 16 by, for example, a vapor deposition method. Note that the organic layer is not separated into the first organic layer 13A and the second organic layer 13B so far, and thus is simply referred to as the organic layer 13. Next, the second electrode 14 is formed on the first surface of the organic layer 13 by, for example, a vapor deposition method or a sputtering method. The second electrode 14 is formed such that its end portion is in contact with the first surface of the cathode contact 17. Next, the protective layer 18 (the first protective layer 18A and the second protective layer 18B) is formed over the entire first surface side of the drive substrate 11 by, for example, a CVD method or a vapor deposition method. Next, as illustrated in FIG. 9, the second protective layer 18B formed in the vicinity of the end portion is partially removed by a dry etching method or the like.

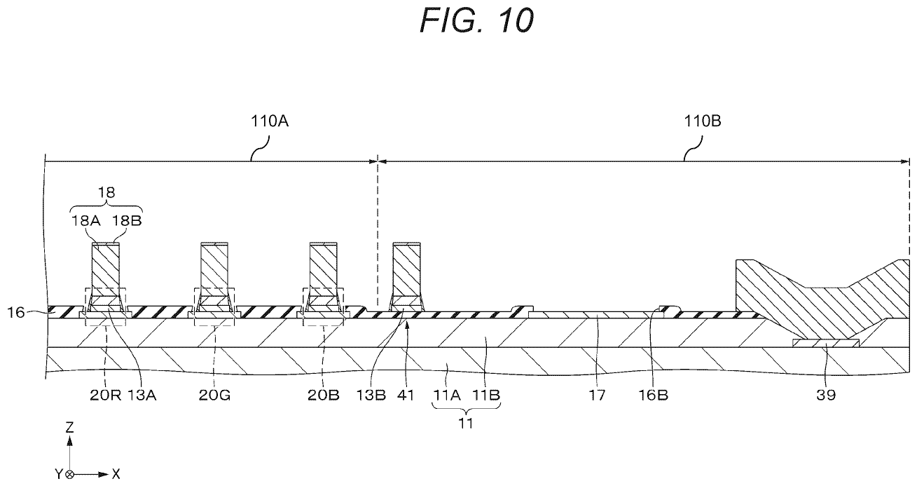

Next, as illustrated in FIG. 10, etching processing is performed to remove the unnecessary protective layer 18. For example, etching processing is performed so as to leave the protective layer 18 on the first surface of the light emitting element 20 and in the vicinity of the end portion of the peripheral region 110B (in the vicinity of the first surface of the connection terminal 39). Moreover, in this process, etching processing is performed so as to partially leave the interpixel insulating layer 16, the organic layer 13 on the first surface of the interpixel insulating layer 16, the second electrode 14 on the first surface of the organic layer 13, and the protective layer 18 on the first surface of the second electrode 14 in the peripheral region 110B. Therefore, the barrier portion 41 is formed. In this process, the organic layer 13 is separated into the first organic layer 13A and the second organic layer 13B. Furthermore, the sidewall protective film 23 is formed by the etching processing in this process.

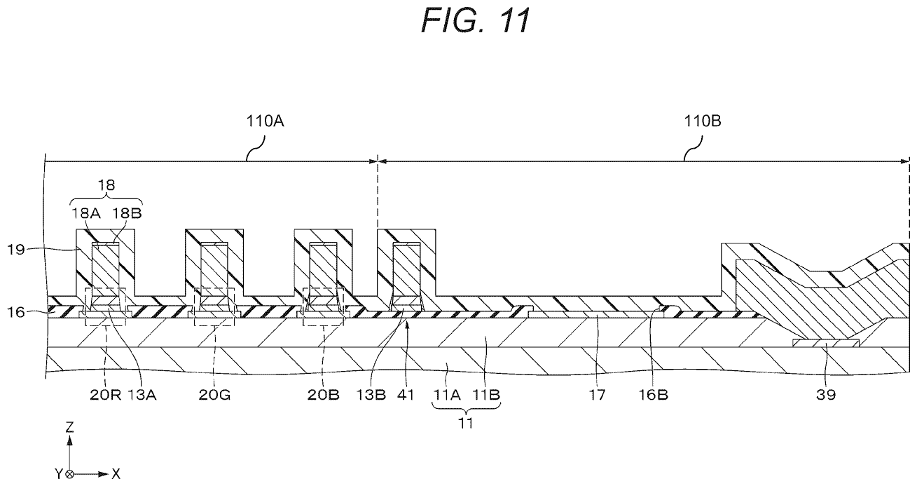

Next, as illustrated in FIG. 11, the separation protective layer 19 is formed over the entire surface by a vapor deposition method or a sputtering method. Then, as illustrated in FIG. 12, after unnecessary portions of the separation protective layer 19 are removed by etching processing, the groove 18C is formed in the protective layer 18 in the effective pixel region 110A. Then, the auxiliary electrode 24 is formed over the cathode contact 17, whereby the second electrode 14 and the cathode contact 17 are connected. Then, the auxiliary electrode protective layer 25 is formed over the entire surface of the drive substrate 11.

Next, the flattening layer 26, the color filter 27, the seal layer 31, the lens 32, the filling layer 33, and the seal portion 38 are formed, the sealing substrate 35 is disposed, and then the seal portion 38 is thermally cured or the like to seal the display device 1000. In these processes, general manufacturing processes of a display device may be performed. Therefore, the display device 1000 illustrated in FIG. 5 can be manufactured. The manufacturing method illustrated here is an example, and the manufacturing method of the display device 1000 is not limited thereto.

### [Effects Obtained by Present Embodiment]

According to the display device 1000 according to the present embodiment, for example, the following effects can be obtained.

By providing the barrier portion including the second organic layer in the light emitting region in the peripheral region of the outer periphery of the effective pixel region, in a case where moisture entering from the outside of the display device reaches a partition wall portion, it is possible to transport (propagate) the moisture along the second organic layer of the partition wall portion. Therefore, entry of moisture into the effective pixel region can be prevented. As a result, it is possible to suppress occurrence of light emission failure or the like, and to provide a highly reliable display device.

Furthermore, by forming the second organic layer of the partition wall portion simultaneously with the first organic layer of the light emitting element, it is not necessary to add a process of forming the second organic layer. Furthermore, since it is not necessary to add the second organic layer as a new configuration element, it is possible to improve the yield of the panel and the reliability of the display device without increasing the cost.

### Second Embodiment

Next, a second embodiment will be described. Note that, in the description of the second embodiment, configurations that are same as or similar to those in the above-described first embodiment are denoted by the same reference signs, and redundant description will be appropriately omitted. Furthermore, the matters described in the first embodiment can be applied to the second embodiment unless otherwise specified. The similarity applies to a third embodiment or the like described later.

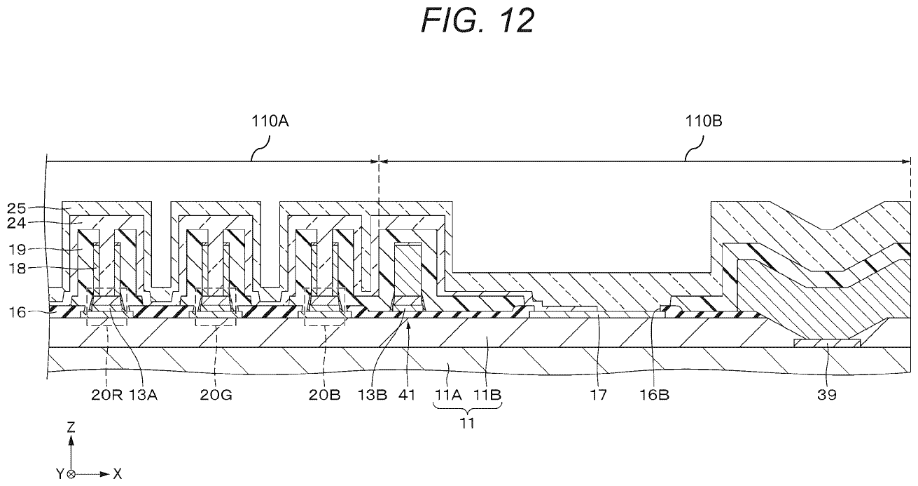

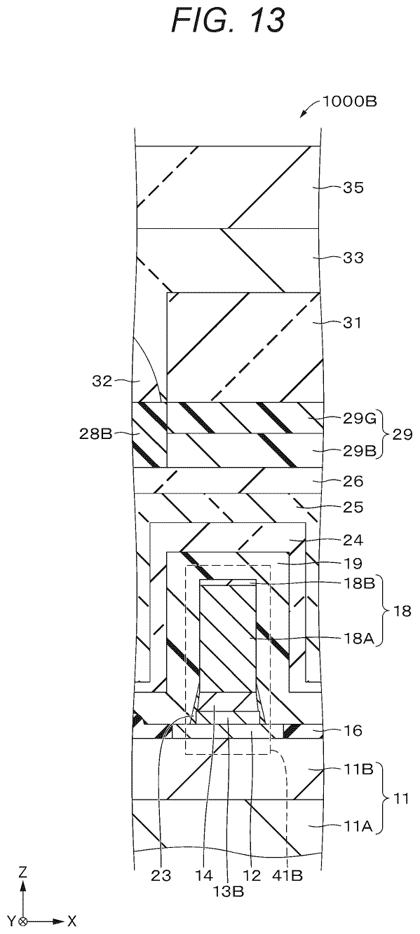

FIG. 13 is an enlarged view of the vicinity of a display device (display device 1000B) barrier portion (barrier portion 41B) according to the second embodiment. In the first embodiment, the second organic layer 13B is layered on the first surface of the interpixel insulating layer 16, but in the second embodiment, the second organic layer 13B is formed on the first surface of the electrode layer. As illustrated in FIG. 13, such an electrode layer is, for example, the same layer as the first electrode 12, that is, a layer formed in the same process as the first electrode 12. The electrode layer may be formed in a different process from the first electrode 12, but the process can be simplified by forming the electrode layer in the same process as the first electrode 12.

In the manufacturing process of the display device 1000B, for example, a configuration similar to the subpixel 100 may be formed as a dummy pixel in the peripheral region 110B. As in the present embodiment, the organic layer in such the dummy pixel may be used as the second organic layer 13B.

The configuration of the display device 1000 according to the first embodiment can be applied to other points. According to the present embodiment, the effects similar to those of the first embodiment can be obtained.

### Third Embodiment

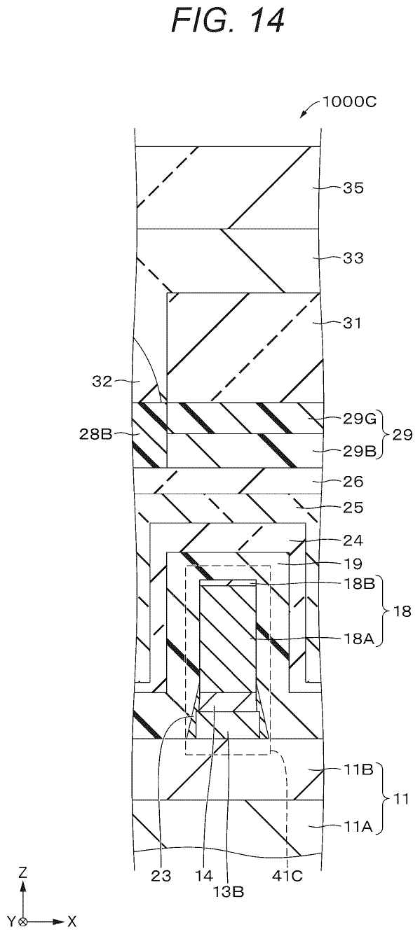

Next, a third embodiment will be described. FIG. 14 is an enlarged view of the vicinity of a display device (display device 1000C) barrier portion (barrier portion 41C) according to the second embodiment. The present embodiment is an example in which the interpixel insulating layer 16 is not formed in the peripheral region 110B. In this case, for example, as illustrated in FIG. 14, the second organic layer 13B is formed on the first surface of the interlayer insulating layer 11B.

The configuration of the display device 1000 according to the first embodiment can be applied to other points. According to the present embodiment, the effects similar to those of the first embodiment can be obtained.

The first to third embodiments described above can be summarized as follows.

In cross-sectional view of the display device 1000, in a case where the number of layers interposed between the first organic layer 13A and the base material 11A is the number of layers M and the number of layers interposed between the second organic layer 13B and the base material 11A is the number of layers N, a difference between the number of layers M and the number of layers N ranges from 0 to 3. The number of layers can be identified on the basis of, for example, a boundary appearing in a transmission electron microscope (TEM) image. At least an interlayer insulating layer 11B is formed between the second organic layer 13B and the base material 11A.

For example, in a case where the first electrode 12 and the interlayer insulating layer 11B are formed between the first organic layer 13A and the base material 11A, the number M of layers interposed between the first organic layer 13A and the base material 11A is 2.

In a case where the interpixel insulating layer 16 and the interlayer insulating layer 11B are formed between the second organic layer 13B and the base material 11A as in the first embodiment (see FIG. 7), the number N of layers interposed between the second organic layer 13B and the base material 11A is 2. That is, a difference between the number of layers M and the number of layers N is 0.

In a case where the electrode layer (for example, the first electrode 12) and the interlayer insulating layer 11B are formed between the second organic layer 13B and the base material 11A as in the second embodiment (see FIG. 13), the number N of layers interposed between the second organic layer 13B and the base material 11A is 2. That is, a difference between the number of layers M and the number of layers N is 0.

As in the third embodiment (see FIG. 14), in a case where only the interlayer insulating layer 11B is formed between the second organic layer 13B and the base material 11A, the number N of layers interposed between the second organic layer 13B and the base material 11A is 1. That is, a difference between the number of layers M and the number of layers N is 1.

Note that the first electrode 12 may have a configuration in which a plurality of layers including different materials are layered instead of a single layer. For example, the first electrode 12 may have a three-layer structure including different materials. In this case, in a case where the first electrode 12 and the interlayer insulating layer 11B are formed between the first organic layer 13A and the base material 11A, the number M of layers interposed between the first organic layer 13A and the base material 11A is 4 (a total of four layers of three layers of the first electrodes 12 and the interlayer insulating layer 11B). In a case where only the interlayer insulating layer 11B is formed between the second organic layer 13B and the base material 11A, the number N of layers interposed between the second organic layer 13B and the base material 11A is 1. That is, a difference between the number of layers M and the number of layers N is 3.

From the above, the difference between the number of layers M and the number of layers N ranges from 0 to 3.

### Fourth Embodiment

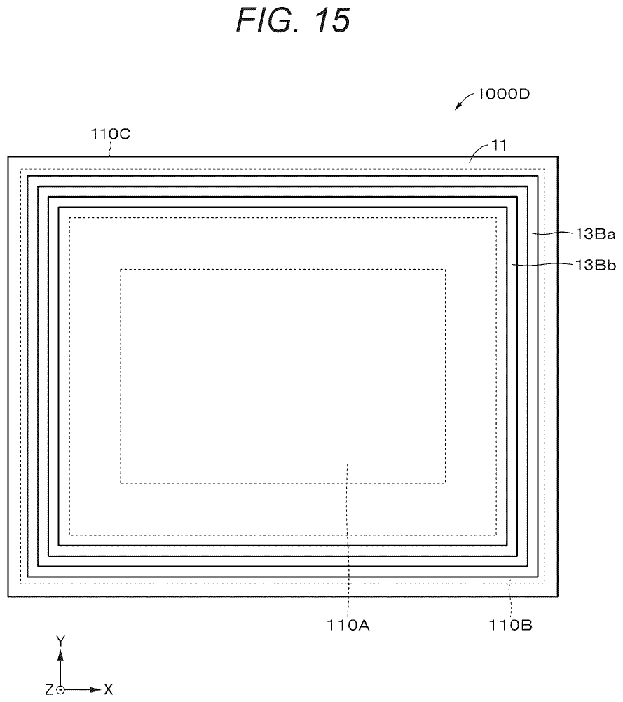

Next, a fourth embodiment will be described. FIG. 15 is a plan view of a display device (display device 1000D) according to the fourth embodiment.

In the first embodiment, the number of second organic layers disposed on the outer periphery of the effective pixel region 110A is one, but may be plural. For example, as illustrated in FIG. 15, two second organic layers (the second organic layer 13Ba and the second organic layer 13Bb) may be formed so as to surround the outer periphery of the effective pixel region 110A.

For example, the amount of moisture entering from the outside is relatively large, and there is a possibility that the water immersion prevention function of the second organic layer 13Ba formed on the outer side collapses, and moisture further enters the inner side. In the present embodiment, since the second organic layer 13Bb is also formed inside, moisture can be propagated into the second organic layer 13Bb even in a case where moisture intrudes into the inside. That is, even in a case where the water immersion prevention function of the second organic layer 13Ba collapses, moisture in the effective pixel region 110A can be prevented. The configuration of the display device 1000 according to the first embodiment can be applied to other points. According to the present embodiment, in addition to the effects described above, the effects similar to those of the first embodiment can be obtained.

### Fifth Embodiment

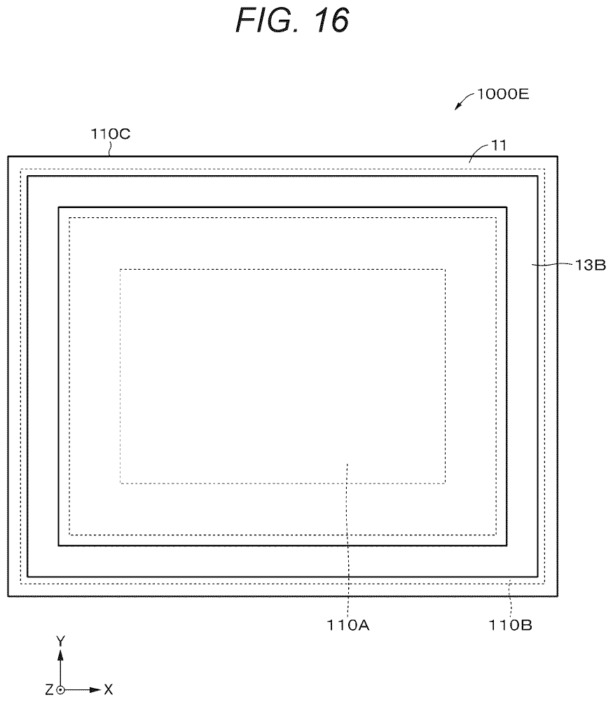

Next, a fifth embodiment will be described. FIG. 16 is a plan view of a display device (display device 1000E) according to the fifth embodiment.

The fifth embodiment is an example in which a length of a width (a length in the X direction or the Y direction in FIG. 16) of the second organic layer 13B is larger than that of the first embodiment. A length of a width of the second organic layer 13B can be appropriately changed. The width of the second organic layer 13B may be the same as or different from a width of the first organic layer 13A. However, from the viewpoint of preventing moisture from entering the effective pixel region 110A by the second organic layer 13B, the size of the width of the second organic layer 13B is preferably larger than the width of the first organic layer 13A.

The configuration of the display device 1000 according to the first embodiment can be applied to other points. According to the present embodiment, the effects similar to those of the first embodiment can be obtained.

### Sixth Embodiment

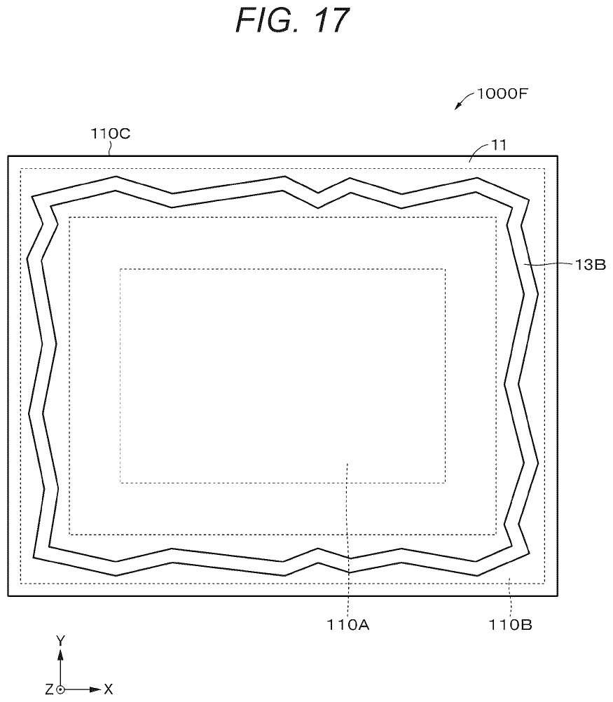

Next, a sixth embodiment will be described. FIG. 17 is a plan view of a display device (display device 1000F) according to the sixth embodiment.

In the first embodiment, the second organic layer 13B is disposed so as to form a linear frame shape, but the second organic layer 13B may be disposed so as to be bent in plan view as illustrated in FIG. 17.

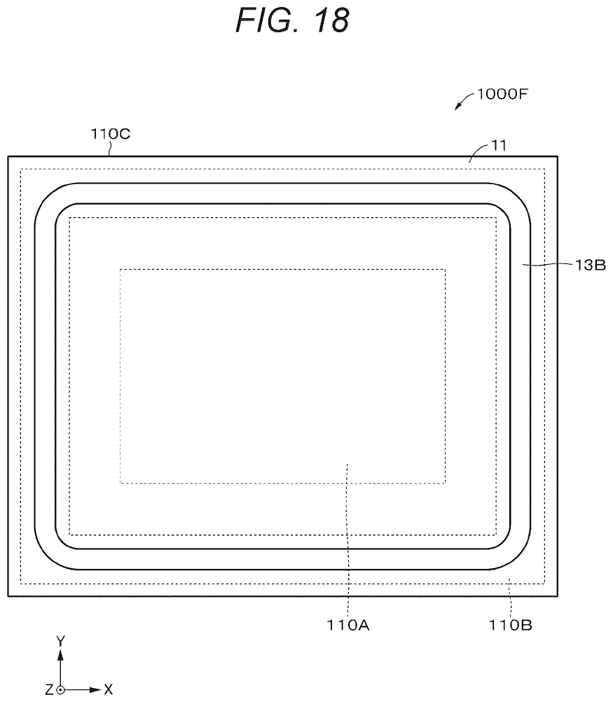

Furthermore, as illustrated in FIG. 18, the second organic layer 13B may be disposed so as to have a shape in which a part (for example, in the vicinity of the corner) is curved.

The configuration of the display device 1000 according to the first embodiment can be applied to other points. According to the present embodiment, the effects similar to those of the first embodiment can be obtained.

### Seventh Embodiment

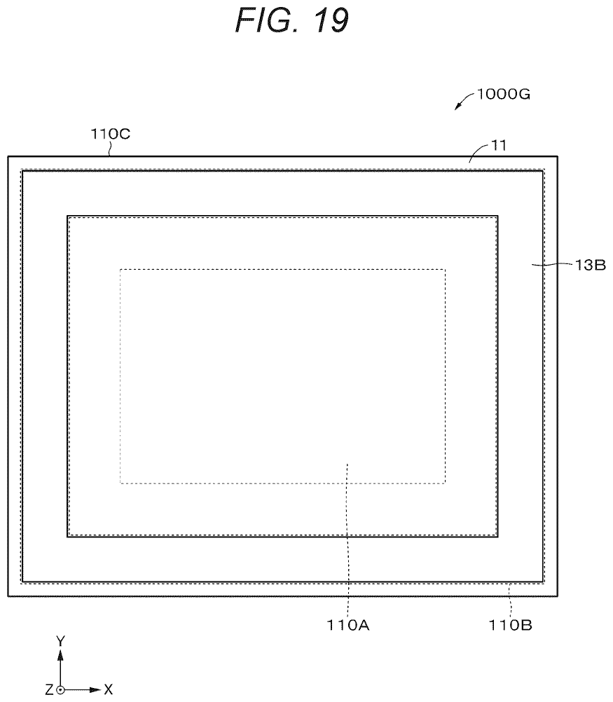

Next, a seventh embodiment will be described. FIG. 19 is a plan view of a display device (display device 1000G) according to the seventh embodiment.

In the present embodiment, the second organic layer 13B is formed closer to the outer edge portion 110C of the drive substrate 11 than in the first embodiment. Since the second organic layer 13B is formed closer to the outer edge portion 110C, the size of the effective pixel region 110A can be increased.

The configuration of the display device 1000 according to the first embodiment can be applied to other points. According to the present embodiment, the effects similar to those of the first embodiment can be obtained.

### Eighth Embodiment

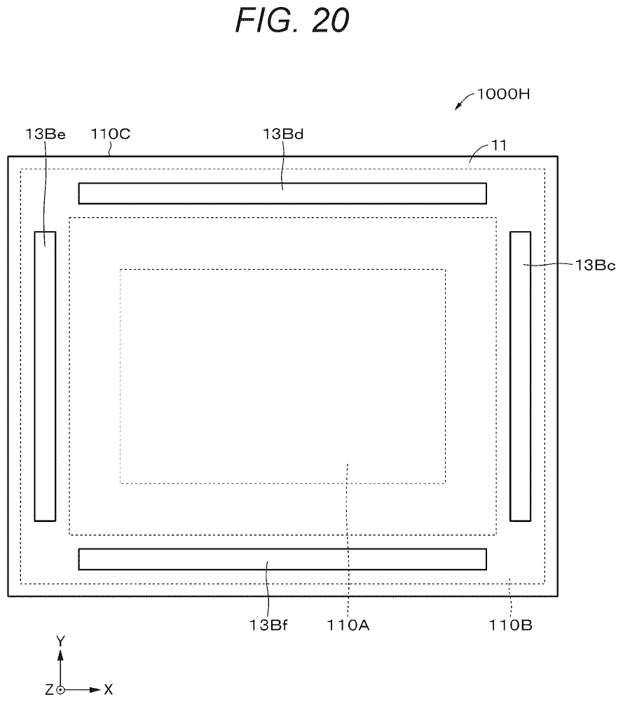

Next, an eighth embodiment will be described. FIG. 20 is a plan view of a display device (display device 1000H) according to the eighth embodiment.

In the first embodiment, the second organic layer 13B is continuously formed around the effective pixel region 110A, but may be partially divided. The example illustrated in FIG. 20 is an example in which the second organic layer is formed by the second organic layer 13Bc, the second organic layer 13Bd, the second organic layer 13Be, and the second organic layer 13Bf separated from each other. From the viewpoint of preventing moisture entry, it is preferable that the second organic layer is continuous so as to surround the effective pixel region 110A, but the shape of the second organic layer partially divided due to restrictions and errors in the manufacturing process is not excluded.

### Ninth Embodiment

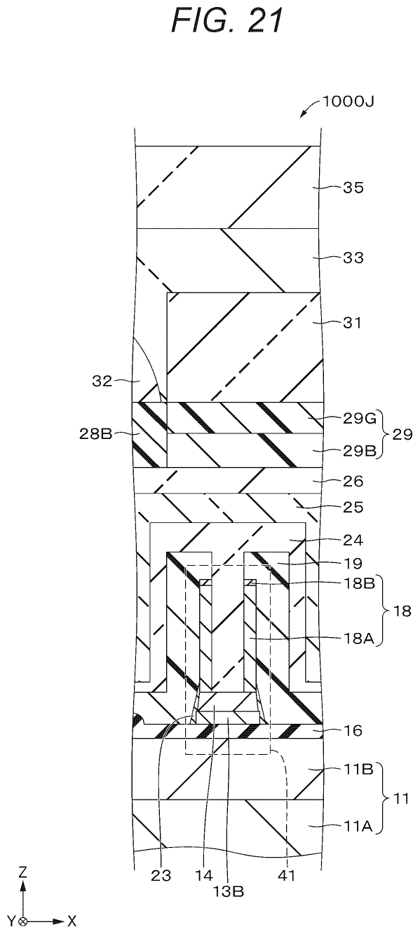

Next, a ninth embodiment will be described. FIG. 21 is an enlarged cross-sectional view illustrating the vicinity of a second organic layer 13B of a display device (display device 1000J) according to the ninth embodiment.

Similarly to the first embodiment, a groove similar to the groove 18C may be formed in a place of the protective layer 18 included in the barrier portion 41. Then, the auxiliary electrode 24 may be connected to the second electrode 14 formed on the first surface of the second organic layer 13B.

The configuration of the display device 1000 according to the first embodiment can be applied to other points. According to the present embodiment, the effects similar to those of the first embodiment can be obtained.

### Tenth Embodiment

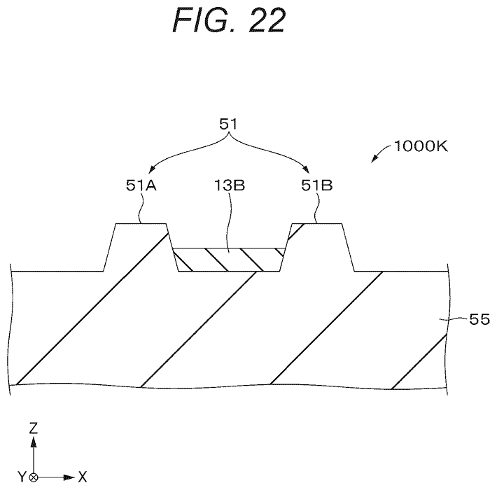

Next, a tenth embodiment will be described. FIG. 22 is an enlarged cross-sectional view illustrating the vicinity of a second organic layer 13B of a display device (display device 1000K) according to the tenth embodiment. As illustrated in FIG. 22, a bank portion 51 is formed in a base layer 55 in the peripheral region 110B. The bank portion 51 includes, for example, two convex portions 51A and 51B formed on the base layer 55. The bank portion 51, specifically, the second organic layer 13B is formed between (inside) the convex portion 51A and the convex portion 51B. The second organic layer 13B can be formed by, for example, an inkjet method.

Note that the base layer 55 may be the interlayer insulating layer 11B, the interpixel insulating layer 16, or other layers. Furthermore, an electrode layer such as the first electrode 12 may be interposed between the second organic layer 13B and the base layer 55. Note that, in FIG. 22, illustration of configurations other than the second organic layer 13B and the base layer 55 is appropriately omitted, but the second electrode 14 and the protective layer 18 may be formed on the first surface side of the second organic layer 13B.

The configuration of the display device 1000 according to the first embodiment can be applied to other points. According to the present embodiment, the effects similar to those of the first embodiment can be obtained.

### Eleventh Embodiment

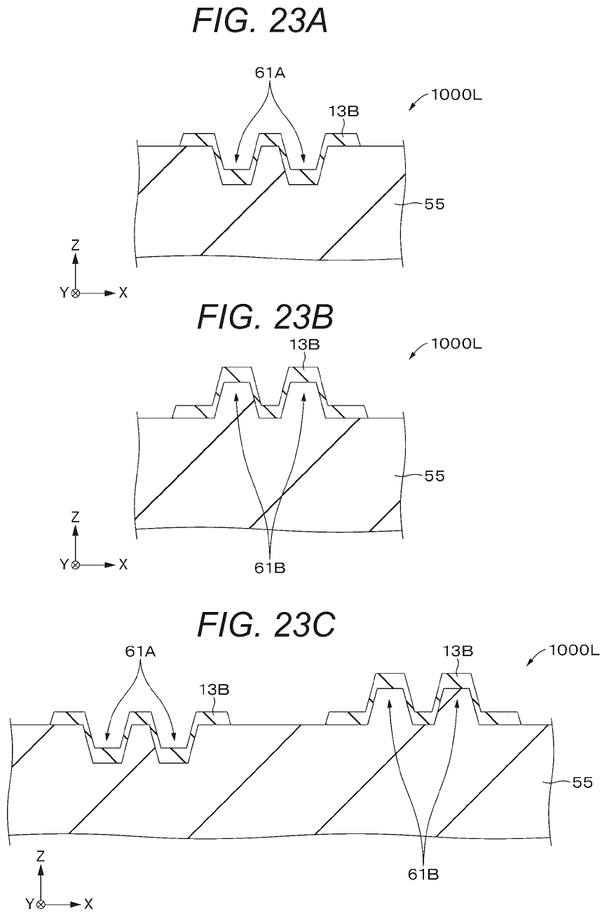

Next, an eleventh embodiment will be described. Each of FIGS. 23A, 23B, and 23C is an enlarged cross-sectional view illustrating the vicinity of the second organic layer 13B of a display device (display device 1000L) according to the eleventh embodiment. As illustrated in FIG. 23A, in the display device 1000L, two concave portions 61A are formed on the first surface of the base layer 55. The second organic layer 13B is formed on the first surface of the concave portion 61A and so as to include a flat portion. The number of concave portions 61A is not limited to two, and may be one or three or more. Furthermore, the second organic layer 13B may be formed on at least a part of the concave portion 61A, and the second organic layer 13B may not be formed on the entire first surface of the concave portion 61A. Note that, as described above, the base layer 55 may be the interlayer insulating layer 11B, the interpixel insulating layer 16, or other layers.

The display device 1000L may include a convex portion 61B formed on the first surface of the base layer 55. For example, as illustrated in FIG. 23B, the display device 1000L may include two convex portions 61B. Then, the second organic layer 13B is formed on the first surface of the convex portion 61B and so as to include a flat portion. The number of the convex portions 61B is not limited to two, and may be one or three or more. The second organic layer 13B may be formed on at least a part of the convex portion 61B, and the second organic layer 13B may not be formed on the entire first surface of the convex portion 61B.

As illustrated in FIG. 23C, the display device 1000L may have a configuration including the concave portion 61A and the convex portion 61B formed on the first surface of the base layer 55.

The configuration of the display device 1000 according to the first embodiment can be applied to other points. For example, the second electrode 14 and the protective layer 18 may be formed on the first surface side of the second organic layer 13B. According to the present embodiment, the effects similar to those of the first embodiment can be obtained. Moreover, in the present embodiment, the length of width (length in the X direction) of the second organic layer 13B can be increased. Therefore, the propagation distance of moisture that has entered the second organic layer 13B can be increased, so that it is possible to effectively prevent the moisture from entering the effective pixel region 110A.

### Twelfth Embodiment

Next, a twelfth embodiment will be described. FIG. 24 is a plan view of a display device (display device 1000M) according to the twelfth embodiment. The emission color of the first organic layer 13A may be red, green, blue, or yellow instead of white light. For example, as illustrated in FIG. 24, in the effective pixel region 110A, a subpixel (an example of a first pixel) including the first organic layer 13A of the emission color of red (R), a subpixel (an example of a second pixel) including the first organic layer 13A of the emission color of green (G), and a subpixel (a third pixel) including the first organic layer 13A of blue (B) may be alternately disposed. Furthermore, in the peripheral region 110B, for example, the second organic layer 13B having a red emission color is formed on the inner side, and the second organic layer 13B having a green emission color is formed on the outer side. Of course, the second organic layer 13B having a blue emission color may be formed in the peripheral region 110B.

The configuration of the display device 1000 according to the first embodiment can be applied to other points. According to the present embodiment, the effects similar to those of the first embodiment can be obtained.

### Example of Resonator Structure Applied to Embodiment

The pixel used in the above-described display device according to the present disclosure may have a configuration including a resonator structure that resonates light generated by the light emitting element. Hereinafter, the resonator structure will be described with reference to the drawings.

### (Resonator Structure: First Example)

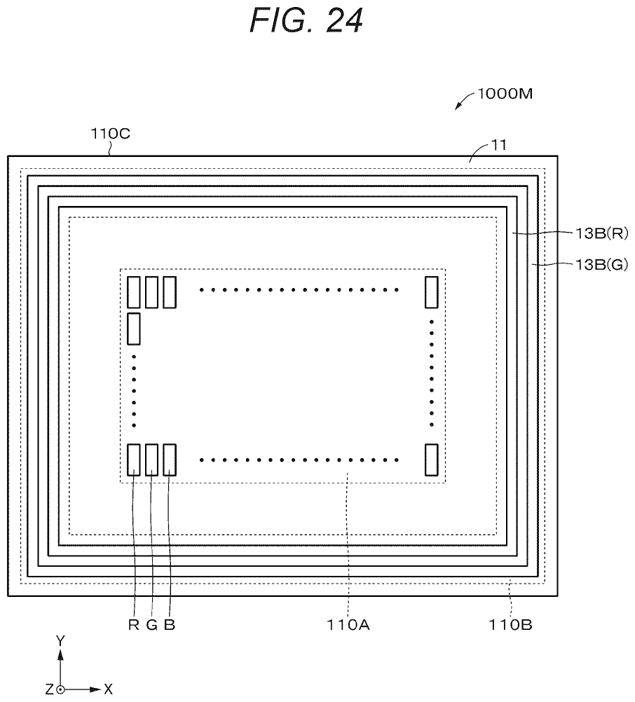

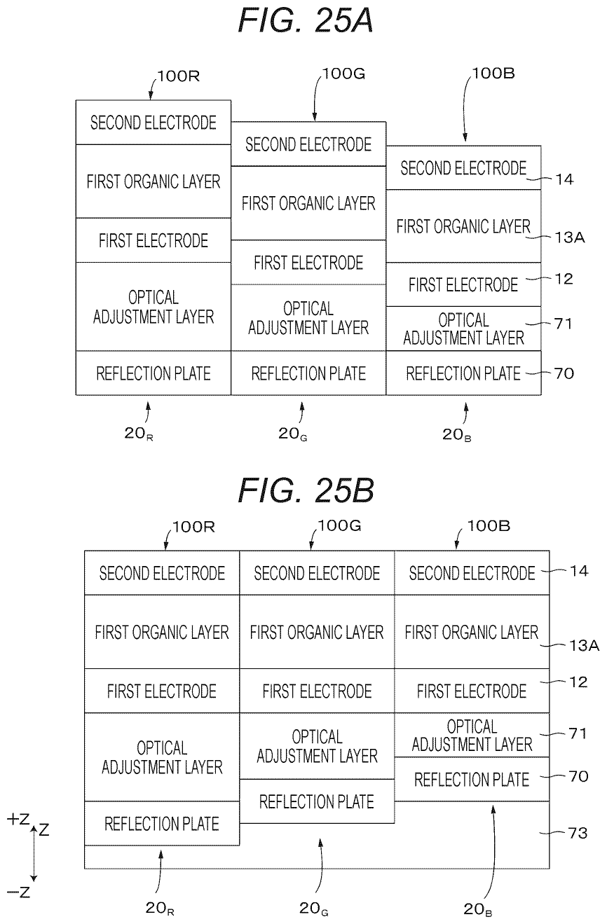

FIG. 25A is a schematic cross-sectional view for explaining a first example of the resonator structure. In the following description, in some cases, the light emitting elements 20 provided corresponding to the subpixels 100R, 100G, and 100B are referred to as light emitting elements 20R, 20G, and 20B, respectively.

Furthermore, in some cases, portions of the first organic layer 13A corresponding to the subpixels 100R, 100G, and 100B are referred to as first organic layers 13AR, 13AG, and 13AB, respectively.

In the first example, the first electrode 12 is formed with a common film thickness in each of the light emitting elements 20. The similarity applies to the second electrode 14.

A reflection plate 70 is disposed below the first electrode 12 of the light emitting element 20 with an optical adjustment layer 71 interposed therebetween. The resonator structure that causes resonance of light generated by the first organic layer 13A is formed between the reflection plate 70 and the second electrode 14. In the following description, the optical adjustment layers 71 provided corresponding to the subpixels 100R, 100G, and 100B are referred to as optical adjustment layers 71R, 71G, and 71B, respectively.

The reflection plate 70 is formed with a common film thickness in each of the light emitting elements 20. A film thickness of the optical adjustment layer 71 varies according to a color to be displayed by the pixel. Since the optical adjustment layers 71R, 71G, and 71B have different film thicknesses, it is possible to set an optical distance at which optimum resonance occurs for a wavelength of light according to the color to be displayed.

In the example illustrated in the drawing, the upper surfaces of the reflection plates 70 in the light emitting elements 20R, 20G, and 20B are disposed so as to be aligned. As described above, because the film thicknesses of the optical adjustment layers 71 are different according to the color to be displayed by the pixel, positions of the upper surfaces of the second electrodes 14 are different according to the types of the light emitting elements 20R, 20G, and 20B.

The reflection plate 70 can include a metal such as aluminum (Al), silver (Ag), or copper (Cu), or an alloy containing these as main components, for example.

The optical adjustment layer 71 can be configured by using an inorganic insulating material such as silicon nitride (SiNx), silicon oxide (SiOx), or silicon oxynitride (SiOxNy), or an organic resin material such as an acrylic resin or a polyimide resin. The optical adjustment layer 71 may be a single layer, or may be a multilayer film including such a plurality of materials. Furthermore, the number of layers may be different according to the types of the light emitting element 20.

The first electrode 12 can be formed using a transparent conductive material such as an indium tin oxide (ITO), an indium zinc oxide (IZO), or a zinc oxide (ZnO).

The second electrode 14 needs to function as a semi-transparent reflective film. The second electrode 14 can include magnesium (Mg), silver (Ag), or a magnesium-silver alloy (MgAg) containing these as main components, and further, an alloy containing an alkali metal or an alkaline earth metal, or the like.

### (Resonator Structure: Second Example)

FIG. 25B is a schematic cross-sectional view for explaining a second example of the resonator structure.

In the second example as well, the first electrode 12 and the second electrode 14 are each formed with a common film thickness in each of the light emitting elements 20.

Then, in the second example as well, the reflection plate 70 is disposed below the first electrode 12 of the light emitting element 20 with the optical adjustment layer 71 interposed therebetween. The resonator structure that causes resonance of light generated by the first organic layer 13A is formed between the reflection plate 70 and the second electrode 14. Similarly to the first example, the reflection plate 70 is formed with a common film thickness in each of the light emitting elements 20, and a film thickness of the optical adjustment layer 71 varies according to a color to be displayed by the pixel.

In the first example illustrated in FIG. 25A, the upper surfaces of the reflection plates 70 in the light emitting elements 20R, 20G, and 20B are disposed so as to be aligned, and positions of the upper surfaces of the second electrodes 14 are different according to the types of the light emitting elements 20R, 20G, and 20B.

On the other hand, in the second example illustrated in FIG. 25B, the upper surfaces of the second electrodes 14 are disposed so as to be aligned with the light emitting elements 20R, 20G, and 20B. In order to align the upper surfaces of the second electrodes 14, in the light emitting elements 20R, 20G, and 20B, the upper surfaces of the reflection plates 70 are disposed in different positions according to the types of the light emitting elements 20R, 20G, and 20B. As a result, the lower surfaces (in other words, the surfaces of a base 73 indicated by reference sign 73 in the drawing) of the reflection plates 70 form a stair shape according to the types of the light emitting elements 20.

Materials and the like constituting the reflection plate 70, the optical adjustment layer 71, the first electrode 12, and the second electrode 14 are similar to those in contents described in the first example, and thus the description thereof is omitted.

### (Resonator Structure: Third Example)

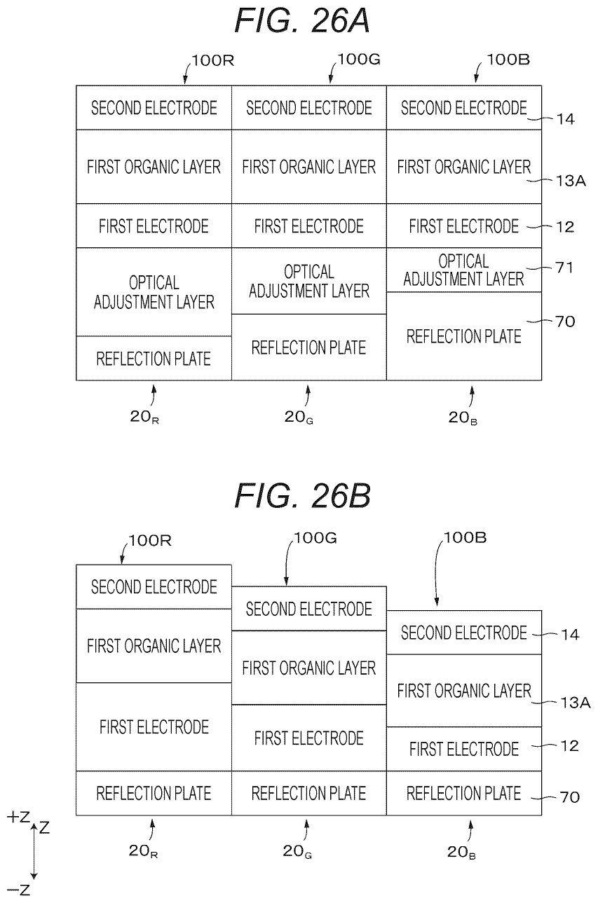

FIG. 26A is a schematic cross-sectional view for explaining a third example of the resonator structure. In the following description, in some cases, the reflection plates 70 provided corresponding to the subpixels 100R, 100G, and 100B are referred to as reflection plates 70R, 70G, and 70B, respectively.

In the third example as well, the first electrode 12 and the second electrode 14 are each formed with a common film thickness in each of the light emitting elements 20.

Then, in the third example as well, the reflection plate 70 is disposed below the first electrode 12 of the light emitting element 20 with the optical adjustment layer 71 interposed therebetween. The resonator structure that causes resonance of light generated by the first organic layer 13A is formed between the reflection plate 70 and the second electrode 14. Similarly to the first and the second examples, the film thickness of the optical adjustment layer 71 varies according to a color to be displayed by the pixel. Then, similarly to the second example, the upper surfaces of the second electrodes 14 are disposed so as to be aligned with the light emitting elements 20R, 20G, and 20B.

In the second example illustrated in FIG. 25B, in order to align the upper surfaces of the second electrodes 14, the lower surfaces of the reflection plates 70 form a stair shape according to the types of the light emitting elements 20.

On the other hand, in the third example illustrated in FIG. 26A, the film thicknesses of the reflection plates 70 are set to be different according to the types of the light emitting elements 20R, 20G, and 20B. More specifically, the film thickness is set so as to align the lower surfaces of the reflection plates 70R, 70G, and 70B.

Materials and the like constituting the reflection plate 70, the optical adjustment layer 71, the first electrode 12, and the second electrode 14 are similar to those in contents described in the first example, and thus the description thereof is omitted.

### (Resonator Structure: Fourth Example)

FIG. 26B is a schematic cross-sectional view for explaining a fourth example of the resonator structure. In the following description, in some cases, the first electrodes 12 provided corresponding to the subpixels 100R, 100G, and 100B are referred to as first electrodes 12R, 12G, and 12B, respectively.

In the first example illustrated in FIG. 25A, the first electrode 12 and the second electrode 14 of each of the light emitting elements 20 are formed with a common film thickness. Then, the reflection plate 70 is disposed below the first electrode 12 of the light emitting element 20 with the optical adjustment layer 71 interposed therebetween.

On the other hand, in the fourth example illustrated in FIG. 26B, the optical adjustment layer 71 is omitted, and the film thicknesses of the first electrodes 12 are set to be different according to the types of the light emitting elements 20R, 20G, and 20B.

The reflection plate 70 is formed with a common film thickness in each of the light emitting elements 20. The film thicknesses of the first electrodes 12 vary according to a color to be displayed by the pixel. By the first electrodes 12R, 12G, and 12B having different film thicknesses, it is possible to set an optical distance that causes optimum resonance for a wavelength of light according to the color to be displayed.

Materials and the like constituting the reflection plate 70, the optical adjustment layer 71, the first electrode 12, and the second electrode 14 are similar to those in contents described in the first example, and thus the description thereof is omitted.

### (Resonator Structure: Fifth Example)

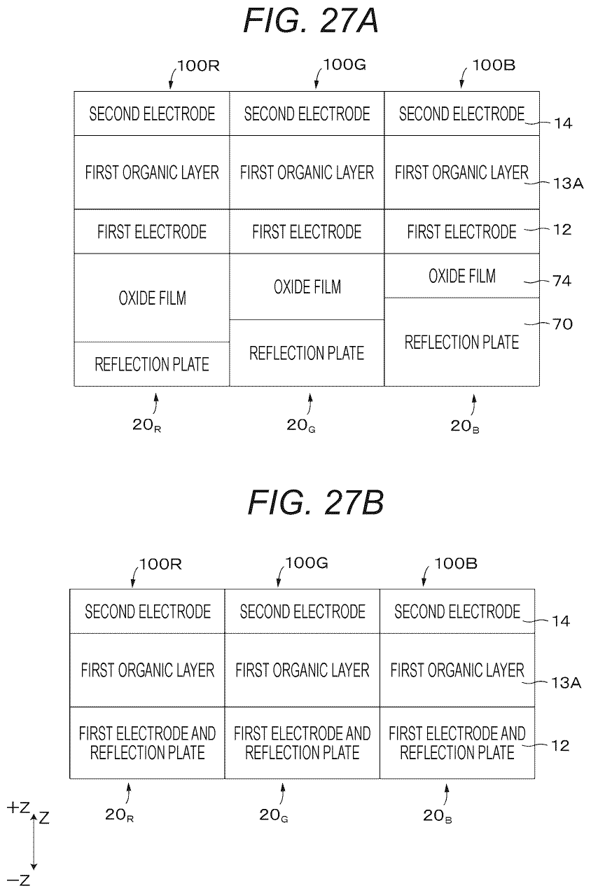

FIG. 27A is a schematic cross-sectional view for explaining a fifth example of the resonator structure.

In the first example illustrated in FIG. 25A, the first electrode 12 and the second electrode 14 are each formed with a common film thickness in each of the light emitting elements 20. Then, the reflection plate 70 is disposed below the first electrode 12 of the light emitting element 20 with the optical adjustment layer 71 interposed therebetween.

On the other hand, in the fifth example illustrated in FIG. 27A, the optical adjustment layer 71 is omitted, and instead, an oxide film 74 is formed on a surface of the reflection plate 70. The film thicknesses of the oxide films 74 are set to be different according to the types of the light emitting elements 20R, 20G, and 20B. In the following description, in some cases, the oxide films 74 provided corresponding to the subpixels 100R, 100G, and 100B are referred to as oxide films 74R, 74G, and 74B, respectively.

The film thickness of the oxide film 74 varies in a manner that depends on the color to be displayed by the pixel. By the oxide films 74R, 74G, and 74B having different film thicknesses, it is possible to set an optical distance for generating optimum resonance for the wavelength of light according to the color to be displayed.

The oxide film 74 is a film obtained by oxidizing the surface of the reflection plate 70, and includes, for example, an aluminum oxide, a tantalum oxide, a titanium oxide, a magnesium oxide, a zirconium oxide, or the like. The oxide film 74 functions as an insulating film for adjusting an optical path length (optical distance) between the reflection plate 70 and the second electrode 14.

The oxide films 74 having different film thicknesses according to the types of the light emitting elements 20R, 20G, and 20B can be formed, for example, as follows.

First, an electrolytic solution is filled in a container, and a substrate on which the reflection plate 70 is formed is immersed in the electrolytic solution. Furthermore, an electrode is disposed to face the reflection plate 70.

Then, a positive voltage is applied to the reflection plate 70 with reference to the electrode to anodize the reflection plate 70. A film thickness of the oxide film obtained as a result of the anodization is proportional to a voltage value for the electrode. Accordingly, the anodization is performed with a voltage according to the types of the light emitting elements 20 applied to each of the reflection plates 70R, 70G, and 70B. As a result, the oxide films 74 having different film thicknesses can be collectively formed.

Materials and the like constituting the reflection plate 70, the first electrode 12, and the second electrode 14 are similar to those in contents described in the first example, and thus description thereof is omitted.

### (Resonator Structure: Sixth Example)

FIG. 27B is a schematic cross-sectional view for explaining a sixth example of the resonator structure.

In the sixth example, the light emitting element 20 is configured by layering the first electrode 12, the first organic layer 13A, and the second electrode 14. However, in the sixth example, the first electrode 12 is formed to function as both an electrode and a reflection plate. The first electrode 12 (and reflection plate) includes a material having an optical constant selected according to the types of the light emitting elements 20R, 20G, and 20B. Since a phase shift caused by the first electrode 12 (and reflection plate) varies, it is possible to set an optical distance that causes optimum resonance for a wavelength of light according to the color to be displayed.

The first electrode 12 (and reflection plate) can include a single-component metal such as aluminum (Al), silver (Ag), gold (Au), or copper (Cu), or an alloy containing these as main components. For example, the first electrode 12R (and reflection plate) of the light emitting element 20R can include copper (Cu), and the first electrode 12G (and reflection plate) of the light emitting element 20G and the first electrode 12B (and reflection plate) of the light emitting element 20B can include aluminum.

Materials and the like constituting the second electrode 14 are similar to those in contents described in the first example, and thus, the description thereof is omitted.

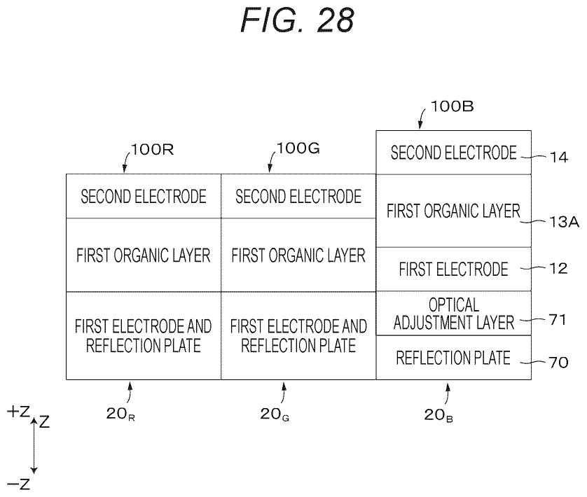

(Resonator structure: Seventh example) FIG. 28 is a schematic cross-sectional view for explaining a seventh example of the resonator structure.

The seventh example basically has a configuration in which the sixth example is applied to the light emitting elements 20R and 20G, and the first example is applied to the light emitting element 20B. With this configuration as well, it is possible to set an optical distance that causes optimum resonance for a wavelength of light according to the color to be displayed.

The first electrodes 12R and 12G (and reflection plates) used for the light emitting elements 20R and 20G can include a single-component metal such as aluminum (Al), silver (Ag), gold (Au), or copper (Cu), or an alloy containing these as main components.

Materials and the like constituting the reflection plate 70B, the optical adjustment layer 71B, and the first electrode 12B used for the light emitting element 20B are similar to those in contents described in the first example, and thus, the description thereof is omitted.

### Relationship Among Normal Lines Passing Through Respective Centers of Light Emitting Unit, Lens Member, and Wavelength Selection Unit

The above-described display device may include a lens array (not illustrated) between the protective layer 18 and the color filter 27. The display device may further include a flattening layer (not illustrated) between the color filter 27 and the lens array.

The lens array includes a plurality of lenses. Each of the lenses may be an on chip microlens. The plurality of lenses is two-dimensionally arranged on the first surface of the color filter 27 or the flattening layer in a prescribed arrangement pattern. One subpixel includes one or two lenses. The lens condenses the light emitted upward in the front direction. The lens has, for example, a convex curved surface protruding in the front direction. The convex curved surface has, for example, a dome shape. Here, the dome shape includes shapes such as a substantially parabolic shape, a substantially hemispherical shape, and a substantially semielliptical sphere.

The lens includes, for example, an inorganic material or a polymer resin transparent to visible light. The inorganic material includes, for example, silicon oxide (SiOx). The polymer resin includes, for example, an ultraviolet curable resin.

In the description below, a relationship among a normal line LN extending through a center of a light emitting unit, a normal line LN′ extending through a center of a lens member, and a normal line LN″ extending through a center of a wavelength selection unit is described. Here, a light emitting unit 81 described below is, for example, the above-described light emitting element 20. Furthermore, a lens member 83 described below is, for example, the lens of the above-described lens array. Furthermore, a wavelength selection unit 82 described below is, for example, the color filter 27.

Note that the size of the wavelength selection unit may be changed as appropriate in accordance with light emitted from the light emitting unit, or, in a case where a light absorbing unit (for example, a black matrix unit) is provided between the wavelength selection units of the adjacent light emitting units, the size of the light absorbing unit may be changed as appropriate in accordance with light emitted from the light emitting unit. Furthermore, the size of the wavelength selection unit may be changed as appropriate in accordance with a distance (offset amount) d0 between the normal line passing through the center of the light emitting unit and the normal line passing through the center of the wavelength selection unit. The planar shape of the wavelength selection unit may be the same as, similar to, or different from the planar shape of the lens member.

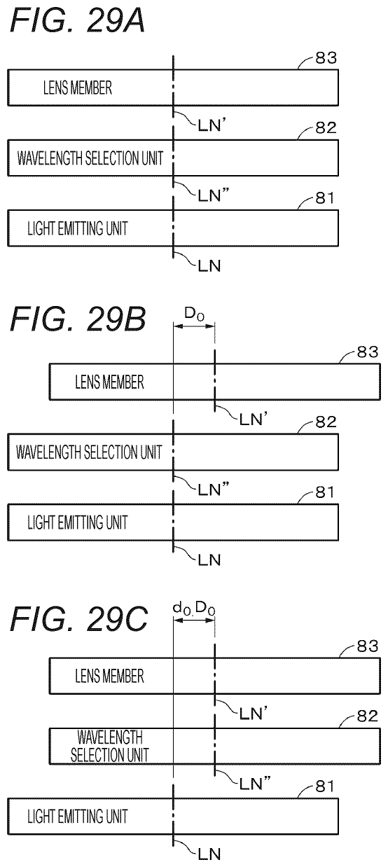

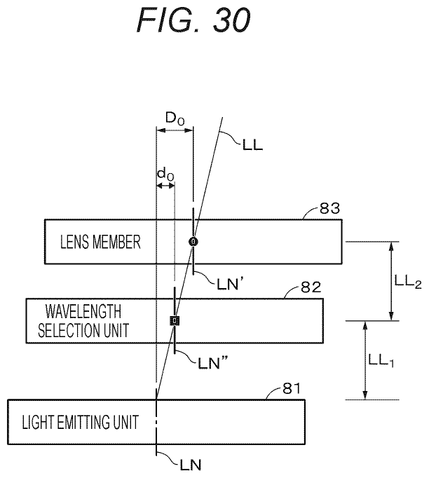

Hereinafter, with reference to FIGS. 29A, 29B, 29C, and 30, a relationship among the normal lines each passing through the center of each unit in a case where the light emitting unit 81, the wavelength selection unit 82, and the lens member 83 are disposed in this order will be described.

As illustrated in FIG. 29A, the normal line LN passing through the center of the light emitting unit 81, the normal line LN″ passing through the center of the wavelength selection unit 82, and the normal line LN′ passing through the center of the lens member 83 may coincide with each other. That is, D0=0 and d0=0 may be satisfied. Here, D0 represents a distance (offset amount) between the normal line LN passing through the center of the light emitting unit 81 and the normal line LN′ passing through the center of the lens member 83, and d0 represents a distance (offset amount) between the normal line LN passing through the center of the light emitting unit 81 and the normal line LN″ passing through the center of the wavelength selection unit 82.

As illustrated in FIG. 29B, it may be configured that the normal line LN passing through the center of the light emitting unit 81 and the normal line LN″ passing through the center of the wavelength selection unit 82 coincide with each other, but the normal line LN extending through the center of the light emitting unit 81 and the normal line LN″ passing through the center of the wavelength selection unit 82 do not coincide with the normal line LN′ passing through the center of the lens member 83. That is, D0>0 and d0=0 may be satisfied.

As illustrated in FIG. 29C, it may be configured that the normal line LN passing through the center of the light emitting unit 81 does not coincide with the normal line LN″ passing through the center of the wavelength selection unit 82 and the normal line LN′ passing through the center of the lens member 83, and the normal line LN″ passing through the center of the wavelength selection unit 82 coincides with the normal line LN′ passing through the center of the lens member 83. That is, D0>0, d0>0, and D0=d0 may be satisfied.

As illustrated in FIG. 30, it may be configured that the normal line LN passing through the center of the light emitting unit 81, the normal line LN″ passing through the center of the wavelength selection unit 82, and the normal line LN′ passing through the center of the lens member 83 do not coincide with each other. That is, D0>0, d0>0, and D0≠d0 may be satisfied. Here, the center of the wavelength selection unit 82 (position indicated by a black square in FIG. 30) is preferably located on a straight line LL connecting the center of the light emitting unit 81 and the center of the lens member 83 (position indicated by a black circle in FIG. 30). Specifically, assuming that a distance in a thickness direction (vertical direction in FIG. 30) between the center of the light emitting unit 81 and the center of the wavelength selection unit 82 is LL1, and that a distance in the thickness direction between the center of the wavelength selection unit 82 and the center of the lens member 83 is LL2, it is preferable that

D0>d0>0

is satisfied, and with manufacturing variations being taken into consideration,

D0: D0=LL1:(LL1+LL2)

is satisfied.

Here, the thickness direction indicates a thickness direction of the light emitting unit 81, the wavelength selection unit 82, and the lens member 83.

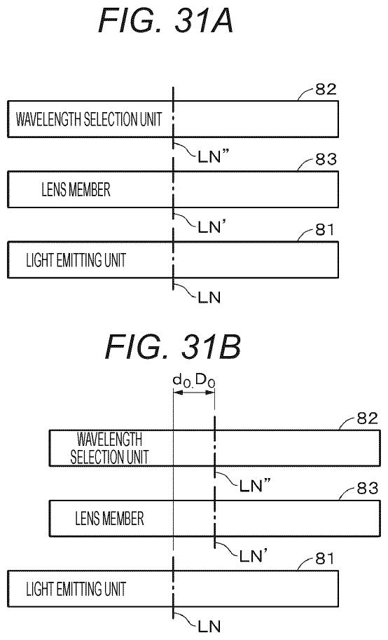

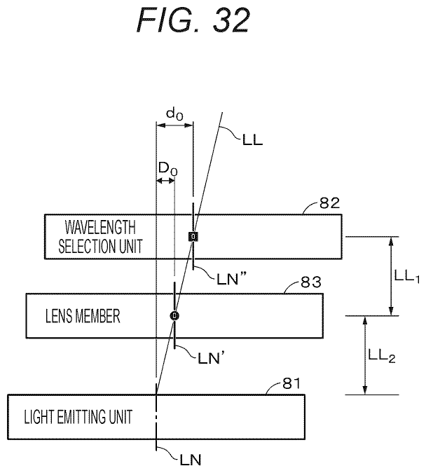

Hereinafter, with reference to FIGS. 31A, 31B, and 32, a relationship among the normal lines each passing through the center of each unit in a case where the light emitting unit 81, the lens member 83, and the wavelength selection unit 82 are disposed in this order will be described.

As illustrated in FIG. 31A, it may be configured that the normal line LN passing through the center of the light emitting unit 81, the normal line LN″ passing through the center of the wavelength selection unit 82, and the normal line LN′ passing through the center of the lens member 83 coincide with each other. That is, D0>0 and d0=0 may be satisfied.

As illustrated in FIG. 31B, it may be configured that the normal line LN passing through the center of the light emitting unit 81 does not coincide with the normal line LN″ passing through the center of the wavelength selection unit 82 and the normal line LN′ passing through the center of the lens member 83, and the normal line LN″ passing through the center of the wavelength selection unit 82 coincides with the normal line LN′ passing through the center of the lens member 83. That is, D0>0, d0>0, and D0=d0 may be satisfied.

As illustrated in FIG. 32, it may be configured that the normal line LN passing through the center of the light emitting unit 81, the normal line LN″ passing through the center of the wavelength selection unit 82, and the normal line LN′ passing through the center of the lens member 83 do not coincide with each other. Here, the center of the lens member 83 (the position indicated by a black circle in FIG. 32) is preferably located on a straight line LL connecting the center of the light emitting unit 81 and the center of the wavelength selection unit 82 (position indicated by a black square in FIG. 32). Specifically, assuming that a distance in a thickness direction (vertical direction in FIG. 32) between the center of the light emitting unit 81 and the center of the lens member 83 is LL2, and that a distance in the thickness direction between the center of the lens member 83 and the center of the wavelength selection unit 82 is LL1, it is preferable that

d0>D0>0

is satisfied, and with manufacturing variations being taken into consideration,

D0:d0=LL2:(LL1+LL2)

is satisfied.

Here, the thickness direction indicates a thickness direction of the light emitting unit 81, the wavelength selection unit 82, and the lens member 83.

### Application Examples

### (Electronic Equipment)

The display device according to the embodiments described above may be provided in various electronic equipment. The display device is suitable especially for an electronic viewfinder of a video camera or a single-lens reflex camera, a head-mounted display, or the like that requires high resolution and is used near the eyes in an enlarged manner.

### (Specific Example 1)

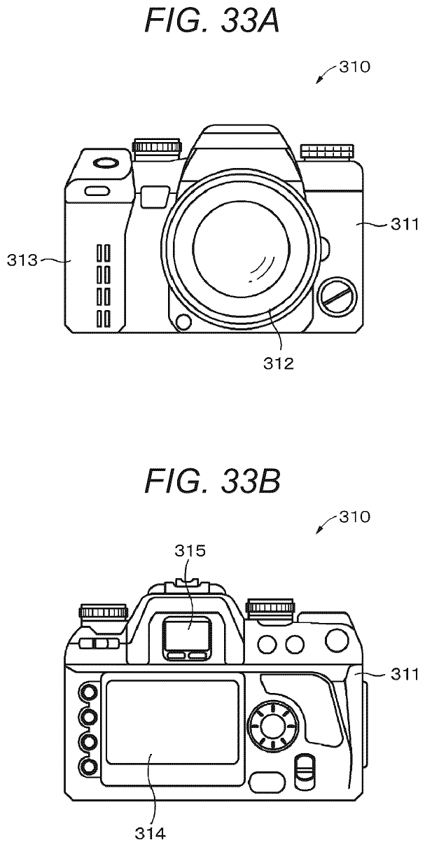

FIGS. 33A and 33B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip portion 313 to be held by a person who captures an image on the front left side.

A monitor 314 is provided at a position shifted to the left side from the center of the back surface of the camera main body 311. An electronic viewfinder (eyepiece window) 315 is provided above the monitor 314. By looking through the electronic viewfinder 315, the photographer can visually recognize an optical image of a subject guided from the imaging lens unit 312, and determine a picture composition. The electronic viewfinder 315 includes the display device according to the embodiments described above.

### (Specific Example 2)

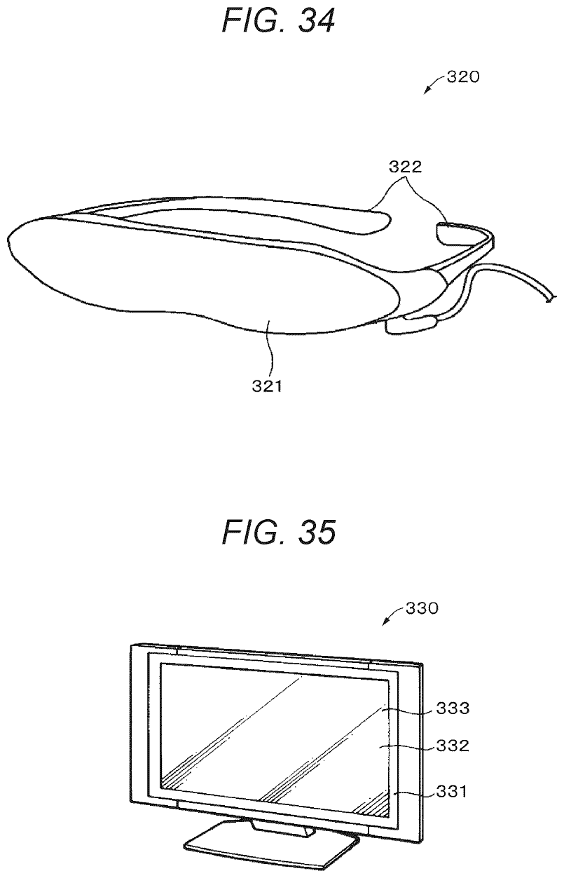

FIG. 34 illustrates an example of an external appearance of a head-mounted display 320. The head-mounted display 320 includes, for example, ear hooking portions 322 for a user to wear the head-mounted display on the head, on both sides of a display unit 321 having a shape of eyeglasses. The display unit 321 includes the display device according to the embodiments described above.

### (Specific Example 3)

FIG. 35 illustrates an example of an external appearance of a television device 330. The television device 330 includes, for example, a video display screen unit 331 including a front panel 332 and a filter glass 333, and the video display screen unit 331 includes the display device according to the embodiments described above.

### (Specific Example 4)

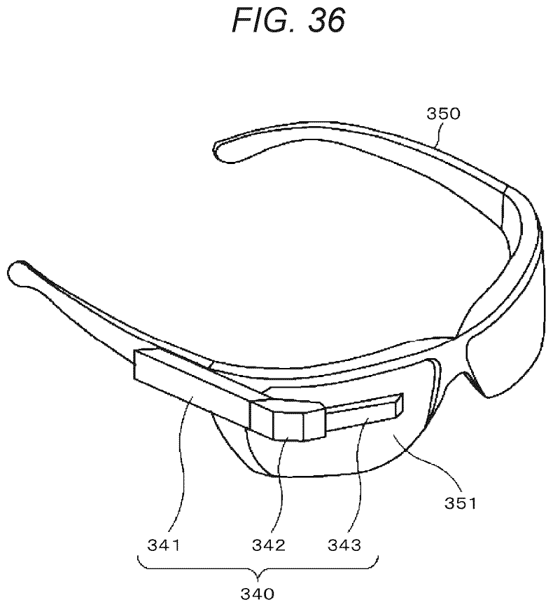

FIG. 36 illustrates an example of an external appearance of a see-through head-mounted display 340. The see-through head-mounted display 340 includes a main body 341, an arm 342, and a lens barrel 343.

The main body 341 is connected to the arm 342 and eyeglasses 350. Specifically, the end of the main body 341 in the long side direction is coupled to the arm 342, and one side of the side surface of the main body 341 is coupled to the eyeglasses 350 via a connecting member. Note that the main body 341 may be mounted directly on the head of the human body.

The main body 341 includes a control board for controlling operations of the see-through head-mounted display 340, and a display unit. The arm 342 connects the main body 341 and the lens barrel 343, and supports the lens barrel 343. Specifically, the arm 342 is coupled to each of the end of the main body 341 and the end of the lens barrel 343, and fixes the lens barrel 343. Furthermore, the arm 342 incorporates a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes the display device according to the embodiments described above.

### (Specific Example 5)

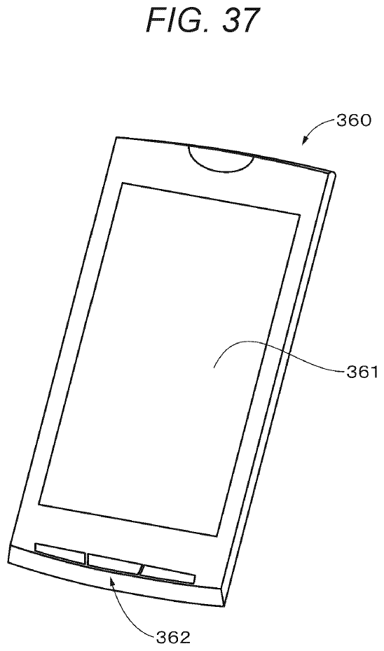

FIG. 37 illustrates an example of an external appearance of a smartphone 360. The smartphone 360 includes a display unit 361 that displays various types of information, an operation unit 362 formed with buttons for receiving operation inputs from the user, and the like. The display unit 361 includes the display device according to the embodiments described above.

### (Specific Example 6)

The display device 101 and the like described above may be included in a vehicle or in various displays.

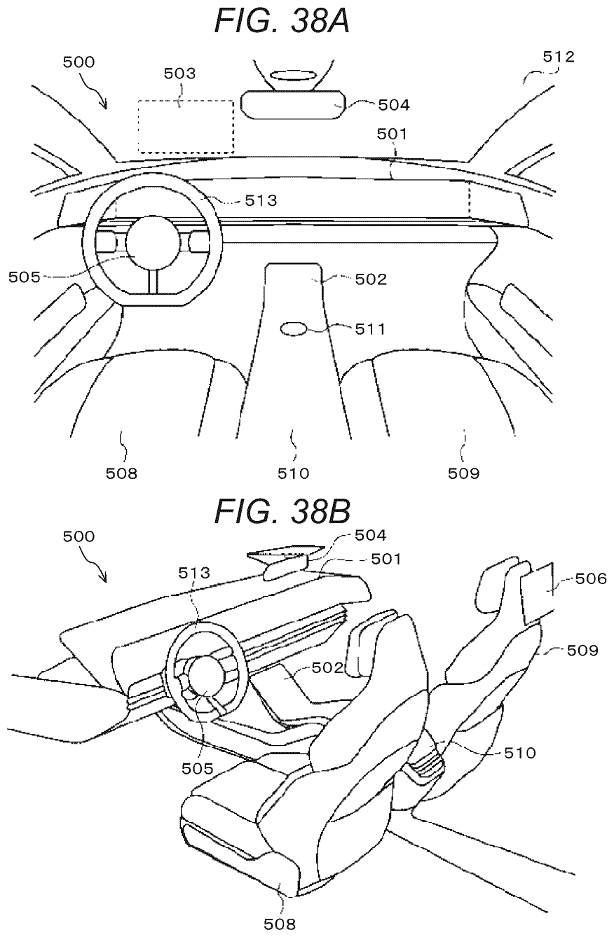

FIGS. 38A and 38B are diagrams illustrating an example of an internal configuration of a vehicle 500 provided with various displays. Specifically, FIG. 38A is a diagram illustrating an example of an internal state of the vehicle 500 as viewed from the rear to the front of the vehicle 500, and FIG. 38B is a diagram illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes the display device according to the embodiments described above. For example, all of these displays may include the display device according to the embodiments described above.

The center display 501 is disposed on the dashboard at a location facing a driver's seat 508 and a passenger seat 509. FIGS. 38A and 38B illustrate an example of the center display 501 having a horizontally long shape extending from a side of the driver's seat 508 to a side of the passenger seat 509, but the screen size and the arrangement place of the center display 501 are optional. The center display 501 can display information sensed by various sensors. As a specific example, the center display 501 can display an image captured by an image sensor, a distance image of an obstacle in front of or on a side of the vehicle 500, the distance being measured by a time-of-flight (ToF) sensor, a body temperature of a passenger detected by an infrared sensor, and the like. The center display 501 can be used to display, for example, at least one of safety-related information, operation-related information, a life log, health-related information, authentication/identification-related information, and entertainment-related information.

The safety-related information is information such as doze sensing, looking-away sensing, sensing of mischief of a child riding together, and presence or absence of wearing of a seat belt, sensing of leaving of an occupant, and is information sensed by a sensor arranged, for example, to overlap with the back surface side of the center display 501. The operation-related information is information obtained by using the sensor to detect gestures related to operations by the occupant. Gestures to be sensed may include operations of various types of equipment in the vehicle 500. For example, operations of air conditioning equipment, a navigation device, an audiovisual (AV) device, a lighting device, and the like are detected. The life log includes life logs of all the occupants. For example, the lifelogs include an action record of each occupant in the vehicle. By acquiring and storing the life log, a condition of the occupant can be confirmed at a time of an accident. The health-related information senses the body temperature of the occupant, by using a sensor such as a temperature sensor, and estimates the health condition of the occupant on the basis of the sensed body temperature. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information on a keyless entry function of performing face authentication by using a sensor, and a function of automatically adjusting a seat height and position through face identification. The entertainment-related information includes information on a function of detecting, with a sensor, operation information about an AV device being used by the occupant, and a function of recognizing the face of the occupant with the sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display a distance image to an obstacle present in the surroundings of the vehicle.

The head-up display 503 is virtually displayed behind a windshield 512 in front of the driver's seat 508. The head-up display 503 can be used to display, for example, at least one of the safety-related information, the operation-related information, the life log, the health-related information, the authentication/identification-related information, and the entertainment-related information. Being virtually arranged in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is arranged near the center of a steering wheel 513 of the vehicle 500. The steering wheel display 505 can be used to display, for example, at least one of the safety-related information, the operation-related information, the life log, the health-related information, the authentication/identification-related information, and the entertainment-related information. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back surface side of the driver's seat 508 or the passenger seat 509, and is for the occupant in the rear seat to enjoy viewing/listening. The rear entertainment display 506 can be used to display, for example, at least one of the safety-related information, the operation-related information, the life log, the health-related information, the authentication/identification-related information, and the entertainment-related information. In particular, because the rear entertainment display 506 is located in front of the occupant in the rear seat, information related to the occupant in the rear seat is displayed on the rear entertainment display. For example, information regarding the operation of the AV device or the air conditioning equipment may be displayed, or a result of measurement of the body temperature or the like of the occupant in the rear seat with a temperature sensor may be displayed on the display.

A sensor may be disposed on the back surface side of the display device in an overlapping manner, so that the distance to an object present in the surroundings can be measured. Optical distance measurement methods are roughly classified into a passive type and an active type. By the method of the passive type, distance measurement is performed by receiving light from an object, without projecting light from a sensor to the object. The method of the passive type includes a lens focus method, a stereo method, a monocular vision method, and the like. By the method of the active type, distance measurement is performed by projecting light onto an object, and receiving reflected light from the object with a sensor to measure the distance. The method of the active type includes an optical radar method, an active stereo method, an illuminance difference stereo method, a moire topography method, and an interference method. Any of the above-described display device 101 and the like can be used in distance measurement by any of these methods. By using the sensor disposed to overlap the back surface side of the display device according to the embodiments described above, the above-described passive or active distance measurement can be performed.

### Modifications

Although the embodiments of the present disclosure have been described in detail above, the content of the present disclosure is not limited to the above-described embodiments, and various modifications based on the technical idea of the present disclosure are possible.

For example, in the display device according to the embodiments, the first organic layer 13A may be shared by the subpixels. Furthermore, the second electrode 14 may be configured to be shared by the subpixels, and an end portion of the second electrode 14 may be connected to the cathode contact 17. In this case, the auxiliary electrode 24 may not be provided. The second organic layer may emit white light, for example. The material of the second organic layer is preferably the same as, but may be different from, the material of the first organic layer from the viewpoint of simplifying the process.

The configurations, methods, processes, shapes, materials, numerical values, and the like described in the embodiments and the modifications are merely examples, and configurations, methods, processes, shapes, materials, numerical values, and the like different from those described above may be used as necessary. Furthermore, the materials exemplified in the embodiments and the modifications can be used alone or in combination of two or more unless otherwise specified. Furthermore, the configuration elements exemplified in the embodiments and the modifications may be appropriately combined.

Note that the effects described in the present specification are merely examples and are not limited, and other effects may also be achieved.

Furthermore, the present disclosure may also employ the following configurations.

(1)

A display device including
a drive substrate including an effective pixel region and a peripheral region between the effective pixel region and an outer edge portion,
in which the effective pixel region includes a plurality of pixels,
each of the pixels includes a first electrode, a second electrode disposed opposite to the first electrode, and a first organic layer provided between the first electrode and the second electrode and including a light emitting layer, and
the peripheral region includes a second organic layer separated from the first organic layer included in the pixel.
   (2)

The display device according to (1), in which
the drive substrate includes a base material, and
a difference between a number of layers interposed between the first organic layer and the base material and a number of layers interposed between the second organic layer and the base material ranges from 0 to 3 in cross-sectional view.
   (3)

The display device according to (1) or (2), in which
the first electrode and an interlayer insulating layer are formed between the first organic layer and the base material, and
at least the interlayer insulating layer is formed between the second organic layer and the base material.
   (4)

The display device according to (3), in which
the interlayer insulating layer and at least one of an electrode layer and an interpixel insulating layer are formed between the second organic layer and the base material.
   (5)

The display device according to (4), in which
the electrode layer includes a layer same as the first electrode.
   (6)

The display device according to any one of (1) to

(5), in which
the first organic layer and the second organic layer are formed in the same process.
   (7)

The display device according to any one of (1) to (6), in which
the first organic layer is separated for each pixel.
   (8)

The display device according to (7), in which
an emission color of the first organic layer and the second organic layer is white light.
   (9)

The display device according to (7), in which
each of the pixels includes a first pixel, a second pixel, and a third pixel,
a first emission color of the first organic layer included in the first pixel, a second emission color of the first organic layer included in the second pixel, and a third emission color of the first organic layer included in the third pixel are emission colors different from each other, and
an emission color of the second organic layer is any one of the first emission color, the second emission color, and the third emission color.
   (10)

The display device according to (9), in which
the first emission color is red, the second emission color is blue, and the third emission color is green.
   (11)

The display device according to any one of (1) to (10), in which
the second organic layer is formed in a frame shape in a case where the drive substrate is plane-viewed.
   (12)

The display device according to (11), in which
the second organic layer formed in the frame shape is partially divided.
   (13)

The display device according to any one of (1) to (12), further including
a plurality of the second organic layers formed in the frame shape.
   (14)

The display device according to any one of (1) to (13), further including
a bank portion,
in which the second organic layer is formed inside the bank portion.
   (15)

The display device according to any one of (1) to (14), further including
a concave portion formed in the peripheral region,
in which the second organic layer is formed on at least a part of a surface of the concave portion.
   (16)

The display device according to any one of (1) to (15), further including
a convex portion formed in the peripheral region,
in which the second organic layer is formed on at least a part of a surface of the convex portion.
   (17)

Including the display device according to any one of (1) to (16),

(18)

A manufacturing method of a display device, the manufacturing method including:
forming a pixel in an effective pixel region of a drive substrate, the pixel including a first electrode, a second electrode disposed opposite to the first electrode, and a first organic layer provided between the first electrode and the second electrode and including a light emitting layer; and
forming a second organic layer in a peripheral region between the effective pixel region and an outer edge portion of the drive substrate, the second organic layer being separated from the first organic layer included in the pixel.
   (19)

The manufacturing method of a display device according to (18), in which
the first organic layer and the second organic layer are formed in the same process.
   (20)

The manufacturing method of a display device according to (18) or (19), in which
the first organic layer and the second organic layer are formed such that a difference between a number of layers interposed between the first organic layer and a base material included in the drive substrate and a number of layers interposed between the second organic layer and the base material ranges from 0 to 3 in cross-sectional view.

Electronic equipment.

### REFERENCE SIGNS LIST

11 Drive substrate
11A Base material
11B Interlayer insulating layer
12 First electrode
13A First organic layer
13B Second organic layer
16 Interpixel insulating layer
100R, 100G, 100B Subpixel
110A Effective pixel region
110B Peripheral region
110C Outer edge portion
1000 Display device

What is claimed is:

1. A display device comprising
a drive substrate including an effective pixel region and a peripheral region between the effective pixel region and an outer edge portion,
wherein the effective pixel region includes a plurality of pixels,
each of the pixels includes a first electrode, a second electrode disposed opposite to the first electrode, and a first organic layer provided between the first electrode and the second electrode and including a light emitting layer, and
the peripheral region includes a second organic layer separated from the first organic layer included in the pixel.

2. The display device according to claim 1, wherein
the drive substrate includes a base material, and
a difference between a number of layers interposed between the first organic layer and the base material and a number of layers interposed between the second organic layer and the base material ranges from 0 to 3 in cross-sectional view.

3. The display device according to claim 1, wherein
the first electrode and an interlayer insulating layer are formed between the first organic layer and the base material, and
at least the interlayer insulating layer is formed between the second organic layer and the base material.

4. The display device according to claim 3, wherein
the interlayer insulating layer and at least one of an electrode layer and an interpixel insulating layer are formed between the second organic layer and the base material.

5. The display device according to claim 4, wherein
the electrode layer includes a layer same as the first electrode.

6. The display device according to claim 1, wherein
the first organic layer and the second organic layer are formed in a same process.

7. The display device according to claim 1, wherein
the first organic layer is separated for each pixel.

8. The display device according to claim 7, wherein
an emission color of the first organic layer and the second organic layer is white light.

9. The display device according to claim 7, wherein
each of the pixels includes a first pixel, a second pixel, and a third pixel,
a first emission color of the first organic layer included in the first pixel, a second emission color of the first organic layer included in the second pixel, and a third emission color of the first organic layer included in the third pixel are emission colors different from each other, and
an emission color of the second organic layer is any one of the first emission color, the second emission color, and the third emission color.

10. The display device according to claim 9, wherein
the first emission color is red, the second emission color is blue, and the third emission color is green.

11. The display device according to claim 1, wherein
the second organic layer is formed in a frame shape in a case where the drive substrate is plane-viewed.

12. The display device according to claim 11, wherein
the second organic layer formed in the frame shape is partially divided.

13. The display device according to claim 1, further comprising
a plurality of the second organic layers formed in the frame shape.

14. The display device according to claim 1, further comprising
a bank portion,
wherein the second organic layer is formed inside the bank portion.

15. The display device according to claim 1, further comprising
a concave portion formed in the peripheral region,
wherein the second organic layer is formed on at least a part of a surface of the concave portion.

16. The display device according to claim 1, further comprising a convex portion formed in the peripheral region, wherein the second organic layer is formed on at least a part of a surface of the convex portion.

17. Electronic equipment comprising
the display device according to claim 1.

18. A manufacturing method of a display device, the manufacturing method comprising:
forming a pixel in an effective pixel region of a drive substrate, the pixel including a first electrode, a second electrode disposed opposite to the first electrode, and a first organic layer provided between the first electrode and the second electrode and including a light emitting layer; and
forming a second organic layer in a peripheral region between the effective pixel region and an outer edge portion of the drive substrate, the second organic layer being separated from the first organic layer included in the pixel.

19. The manufacturing method of a display device according to claim 18, wherein
the first organic layer and the second organic layer are formed in a same process.

20. The manufacturing method of a display device according to claim 18, wherein
the first organic layer and the second organic layer are formed such that a difference between a number of layers interposed between the first organic layer and a base material included in the drive substrate and a number of layers interposed between the second organic layer and the base material ranges from 0 to 3 in cross-sectional view.
